(19) United States
(12) Patent Application Publication
(10) Pub. No.: US 2024/0419084 A1
(43) Pub. Date: Dec. 19, 2024

(54) OPTICAL PROXIMITY CORRECTION METHOD AND METHOD OF FABRICATING SEMICONDUCTOR DEVICE USING THE SAME

(71) Applicant: Samsung Electronics Co., Ltd., Suwon-si (KR)

(72) Inventors: HEUNGSUK OH, Suwon-si (KR); SANGWOOK KIM, Suwon-si (KR); HEE-JUN LEE, Suwon-si (KR); JEEEUN JUNG, Suwon-si (KR); WOO-YONG CHO, Suwon-si (KR)

(21) Appl. No.: 18/442,205

(22) Filed: Feb. 15, 2024

(30) Foreign Application Priority Data
Jun. 14, 2023 (KR) 10-2023-0076412

(51) Int. Cl. G03F 7/00; G03F 1/36

(52) U.S. Cl. CPC G03F 7/70441; G03F 1/36

(57) ABSTRACT

A method of fabricating a semiconductor device is disclosed. The method includes performing an optical proximity correction (OPC) on a design pattern of a layout and forming a photoresist pattern on a substrate using a photomask manufacture based the corrected layout. The performing of the OPC includes analyzing a cell hierarchy to choose a representative cell in the layout, dividing the design pattern in the representative cell into a plurality of segments including first segments, choosing a first unique segment, which represents the first segments, from the plurality of segments, generating a first correction bias of the first unique segment, applying the first correction bias to all of the first segments to generate a correction pattern, and applying a correction result of the representative cell to other cells that are included in the layout and are of a same type as the representative cell.

### CROSS-REFERENCE TO RELATED APPLICATIONS

This U.S. non-provisional patent application claims priority under 35 U.S.C. § 119 to Korean Patent Application No. 10-2023-0076412, filed on Jun. 14, 2023, in the Korean Intellectual Property Office, the entire contents of which are hereby incorporated by reference.

### BACKGROUND OF THE INVENTION

The present disclosure relates to a method of fabricating a semiconductor device, and in particular, to a method of fabricating a semiconductor device using an optical proximity correction (OPC) method.

Due to their small-sized, multifunctional, and/or low-cost characteristics, semiconductor devices are being esteemed as important elements in the electronics industry.

The semiconductor devices are classified into a memory device for storing data, a logic device for processing data, and a hybrid device including both memory and logic elements. As the electronics industry is highly developed, there is an increasing demand for semiconductor devices with improved characteristics. For example, there is an increasing demand for semiconductor devices with high reliability, high performance, and/or multiple functions. To satisfy these technical requirements, complexity and/or integration density of semiconductor devices are being increased.

### SUMMARY

An embodiment of the inventive concept may provide an OPC method that can preserve the consistency of an OPC process.

An embodiment of the inventive concept may provide a method of fabricating a highly integrated and highly reliable semiconductor device.

According to an embodiment of the inventive concept, a method of fabricating a semiconductor device may include performing an optical proximity correction (OPC) on a design pattern of a layout and forming a photoresist pattern on a substrate using a photomask manufacture based the corrected layout. The performing of the OPC may include analyzing a cell hierarchy to choose a representative cell in the layout, dividing the design pattern in the representative cell into a plurality of segments including first segments, choosing a first unique segment, which represents the first segments, from the plurality of segments, generating a first correction bias of the first unique segment, applying the first correction bias to all of the first segments to generate a correction pattern, and applying a correction result of the representative cell to other cells that are included in the layout and are of a same type as the representative cell.

According to an embodiment of the inventive concept, a method of fabricating a semiconductor device may include performing an optical proximity correction (OPC) on a layout of a memory device and forming a photoresist pattern on a substrate using a photomask manufacture based on the corrected layout. The performing of the OPC may include choosing a representative cell from a plurality of cells in the layout, dividing a design pattern in the representative cell into a plurality of segments, choosing a unique segment from the plurality of segments, and generating a correction bias of the unique segment.

According to an embodiment of the inventive concept, a method of fabricating a semiconductor device may include performing an optical proximity correction (OPC) on a design pattern of a layout, manufacturing a photomask based on the corrected layout, forming an etch-target layer and a photoresist layer on a substrate, performing a photolithography process using the photomask on the photoresist layer to form photoresist patterns, and patterning the etch-target layer using the photoresist patterns. The performing of the OPC may include analyzing a cell hierarchy to choose a representative cell in the layout, dividing the design pattern in the representative cell into a plurality of segments including first and second segments, choosing a first unique segment, which represents the first segments, from the segments, choosing a second unique segment, which represents the second segments, from the segments, generating a first correction bias of the first unique segment, generating a second correction bias of the second unique segment, applying the first correction bias to all of the first segments, and applying the second correction bias to all of the second segments.

### BRIEF DESCRIPTION OF THE DRAWINGS

FIG. 1 is a block diagram illustrating a computer system for performing a semiconductor design process, according to an embodiment of the inventive concept.

FIG. 2 is a flow chart illustrating a method of designing and fabricating a semiconductor device, according to an embodiment of the inventive concept.

FIG. 3 is a conceptual diagram illustrating a photolithography system, in which a photomask according to an embodiment of the inventive concept is used.

FIG. 4 is a conceptual diagram illustrating a layout according to an embodiment of the inventive concept.

FIG. 5 is a conceptual diagram illustrating a process, which is performed to divide a contour of a designed layout of FIG. 4 into a plurality of segments, as a part of the optical proximity correction (OPC) operation according to an embodiment of the inventive concept.

FIG. 6 is a conceptual diagram illustrating a layout corrected by the OPC operation of FIG. 5.

FIG. 7 is a conceptual diagram illustrating a photomask manufactured based on the corrected layout of FIG. 6.

FIG. 8 is a conceptual diagram illustrating a photolithography process of printing a circuit pattern on a substrate, using the photomask of FIG. 7.

FIG. 9 is a flow chart schematically illustrating a detailed process of an OPC operation according to an embodiment of the inventive concept.

FIG. 10 is a flow chart illustrating a process of generating a hash value of a segment according to an embodiment of the inventive concept.

FIGS. 11 and 23 are plan views each illustrating an example of a designed layout according to embodiments of the inventive concept.

FIGS. 12 to 22 are plan views of a portion ‘M’ of FIG. 11 that illustrate an OPC operation according to an embodiment of the inventive concept.

FIG. 24 is a plan view illustrating a photomask according to an embodiment of the inventive concept.

FIG. 25 is a conceptual diagram illustrating a process of forming photoresist patterns on a substrate using the photomask of FIG. 24.

FIGS. 26, 28, 30, 32, 34, 36, 38, and 40 are plan views illustrating a method of fabricating a semiconductor device according to an embodiment of the inventive concept.

FIGS. 27A, 29A, 31A, 33A, 35A, 37A, 39A, and 41A are sectional views taken along lines A-A′ of FIGS. 26, 28, 30, 32, 34, 36, 38, and 40, respectively.

FIGS. 27B, 29B, 31B, 33B, 35B, 37B, 39B, and 41B are sectional views taken along lines B-B′ of FIGS. 26, 28, 30, 32, 34, 36, 38, and 40, respectively.

FIGS. 27C, 29C, 31C, 33C, 35C, 37C, 39C, and 41C are sectional views taken along lines C-C′ of FIGS. 26, 28, 30, 32, 34, 36, 38 and 40, respectively.

FIGS. 27D, 29D, 31D, 33D, 35D, 37D, 39D, and 41D are sectional views taken along lines D-D′ of FIGS. 26, 28, 30, 32, 34, 36, 38 and 40, respectively.

### DETAILED DESCRIPTION

Hereinafter, embodiments are described in detail with reference to the accompanying drawings. The same reference numerals are used for the same components in the drawings, and redundant descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

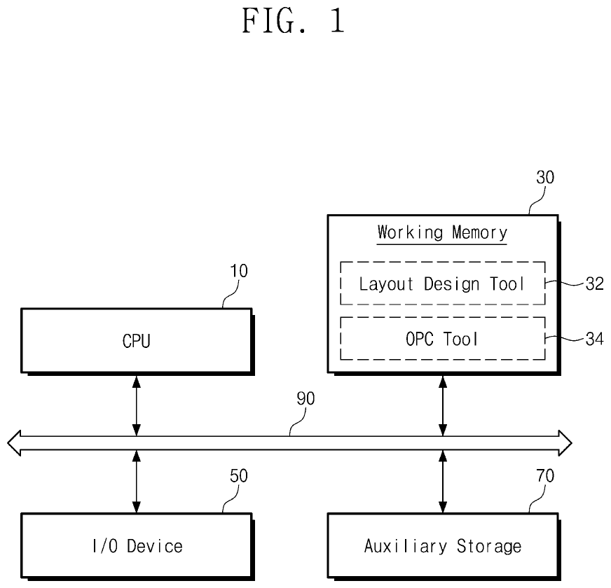

FIG. 1 is a block diagram illustrating a computer system for performing a semiconductor design process, according to an embodiment of the inventive concept. Referring to FIG. 1, a computer system may include a central processing unit (CPU) 10, a working memory 30, an input-output device 50, and an auxiliary storage 70. In an embodiment, the computer system may be a customized system for performing a layout design process according to an embodiment of the inventive concept. Furthermore, the computer system may include a computing system configured to execute various design and check simulation programs.

The CPU 10 may be configured to run a variety of software programs, such as application programs, operating systems, and device drivers. For example, the CPU 10 may be configured to run an operating system (not shown) loaded on the working memory 30. Furthermore, the CPU 10 may be configured to run various application programs on the operating system. For example, the CPU 10 may be configured to run a layout design tool 32 and/or an optical proximity correction (OPC) tool 34 loaded on the working memory 30.

The operating system or application programs may be loaded on the working memory 30. For example, when the computer system starts a booting operation, an OS image (not shown) stored in the auxiliary storage 70 may be loaded on the working memory 30 according to a booting sequence. In the computer system, overall input/output operations may be managed by the operating system. Some application programs, which may be selected by a user or be provided for basic services, may be loaded on the working memory 30. According to an embodiment of the inventive concept, the layout design tool 32 and/or OPC tool 34 may be loaded on the working memory 30, from the auxiliary storage 70.

The layout design tool 32 may provide a function for changing biasing data for specific layout patterns; for example, the layout design tool 32 may be configured to allow the specific layout patterns to have shapes and positions different from those defined by a design rule. The layout design tool 32 may be configured to perform a design rule check (DRC) under the changed condition of the bias data. The OPC tool 34 may be configured to perform an OPC process on layout data, which is obtained by the layout design tool 32. The working memory 30 may be one of volatile memory devices (e.g., static random access memory (SRAM) or dynamic random access memory (DRAM) devices) or nonvolatile memory devices (e.g., PRAM, MRAM, ReRAM, FRAM, NOR FLASH memory devices).

The input-output device 50 may be configured to control user input and output operations of user interface devices. For example, the input-output device 50 may include a keyboard or a monitor, allowing a designer to input relevant information. By using the input-output device 50, the designer may receive information on several regions or data paths, to which adjusted operating characteristics will be applied, of a semiconductor device. The input-output device 50 may be configured to display a progress status or a process result of the OPC tool 34.

The auxiliary storage 70 may serve as a storage medium for the computer system. The auxiliary storage 70 may be configured to store application programs, an OS image, and various data. The auxiliary storage 70 may be provided in the form of one of memory cards (e.g., MMC, eMMC, SD, MicroSD, and so forth) or a hard disk drive (HDD). The auxiliary storage 70 may include a NAND FLASH memory device with a large memory capacity. In other embodiments, the auxiliary storage 70 may include one or more next-generation nonvolatile memory devices (e.g., PRAM, MRAM, ReRAM, or FRAM) or NOR FLASH memory devices.

A system interconnector 90 may serve as a system bus for realizing a network in the computer system. The CPU 10, the working memory 30, the input-output device 50, and the auxiliary storage 70 may be electrically connected to each other through the system interconnector 90, and thus, data may be exchanged therebetween. However, the system interconnector 90 may not be limited to the afore-described configuration; for example, it may further include an additional element for increasing efficiency in data communication.

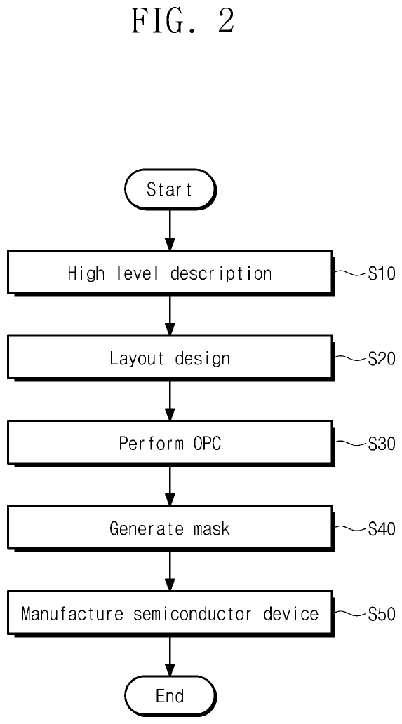

FIG. 2 is a flow chart illustrating a method of designing and fabricating a semiconductor device, according to an embodiment of the inventive concept.

Referring to FIG. 2, a high-level design process for a semiconductor integrated circuit may be performed using the computer system described with reference to FIG. 1 (S10). For example, in the high-level design process, an integrated circuit to be designed may be described using a high-level computer language (e.g., C language). Circuits designed by the high-level design process may be more concretely described by a register transfer level (RTL) coding or a simulation. Furthermore, codes generated by the RTL coding may be converted into a netlist, and the results may be combined with each other to wholly describe a semiconductor device. The combined schematic circuit may be verified by a simulation tool. In an embodiment, an adjusting step may be further performed, in consideration of a result of the verification step.

A layout design process may be performed to realize a logically complete form of the semiconductor integrated circuit on a silicon wafer (S20). For example, the layout design process may be performed, based on the schematic circuit prepared in the high-level design process or the corresponding netlist. The layout design process may include a routing operation of placing and connecting various standard cells that are provided from a cell library, based on a predetermined design rule.

The cell library may contain, but is not limited to, information on operation, speed, and power consumption of cells. In an embodiment, a cell library for representing a layout of a circuit at a gate level may be defined in or by the layout design tool. Here, the layout may be prepared to define or describe shapes, positions, or dimensions of patterns constituting transistors and metal interconnection lines, which will be formed on a silicon wafer. For example, to form an inverter circuit on a silicon wafer, it may be necessary to prepare or draw a layout for patterns (e.g., PMOS, NMOS, N-WELL, gate electrodes, and metal interconnection lines thereon). For this, at least one of the inverters defined in the cell library may be selected.

Furthermore, a routing operation of connecting the selected cells to each other may be performed. In detail, the routing operation may be performed on the selected and placed standard cells to connect them to upper interconnection lines. The afore-described steps may be automatically or manually performed by the layout design tool. Furthermore, an operation of placing and routing the standard cells may be automatically performed by an additional Place & Routing tool.

After the routing operation, a verification operation may be performed on the layout to check whether there is a portion violating the given design rule. In an embodiment, the verification operation may include evaluating verification items, such as a design rule check (DRC), an electrical rule check (ERC), and a layout vs schematic (LVS). The evaluating of the DRC item may be performed to evaluate whether the layout meets the given design rule. The evaluating of the ERC item may be performed to evaluate whether there is an issue of electrical disconnection in the layout. The evaluating of the LVS item may be performed to evaluate whether the layout is prepared to coincide with the gate-level netlist.

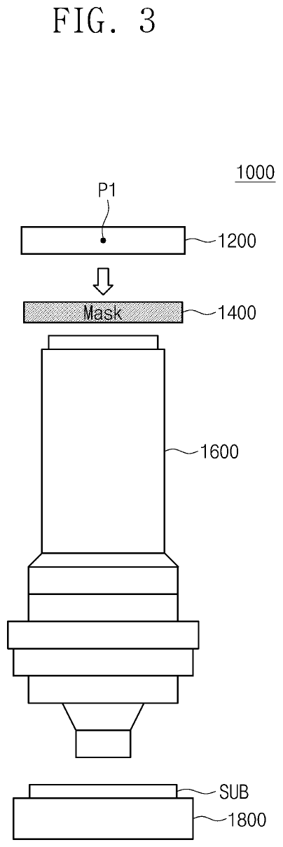

An optical proximity correction (OPC) operation may be performed (S30). The OPC operation may be performed to correct optical proximity effects, which may occur when a photolithography process is performed on a silicon wafer using a photomask manufactured based on the layout. The optical proximity effect may be an unintended optical effect (such as refraction or diffraction), which may occur in the exposing process using the photomask manufactured based on the layout. In the OPC operation, the layout may be modified to reduce a difference in shape between designed patterns and actually-formed patterns, which may be caused by the optical proximity effects. As a result of the OPC operation, the shapes and positions of patterns in the designed layout may be changed or biased. The OPC operation will be described in more detail with reference to FIGS. 3 to 8.

A photomask may be manufactured, based on the layout modified by the OPC operation (S40). In general, the photomask may be manufactured by patterning a chromium layer provided on a glass substrate using the layout pattern data.

The photomask manufactured may be used to manufacture a semiconductor device (S50). In the actual fabricating process, the exposing and etching operations may be repeatedly performed, and thus, patterns defined in the layout design process may be sequentially formed on a semiconductor substrate.

FIG. 3 is a schematic diagram illustrating a photolithography system, in which a photomask according to an embodiment of the inventive concept is used. A photolithography system 1000 may include a light source 1200, a photomask 1400, a reduction projection apparatus 1600, and a substrate stage 1800. Although not illustrated in FIG. 3, some additional elements may be provided in the photolithography system 1000. For example, the photolithography system 1000 may further include a sensor for measuring a height and a slope of a top surface of a substrate SUB.

The light source 1200 may be configured to emit light. The light emitted from the light source 1200 may be incident into the photomask 1400. To control a focal length, a lens may be provided between the light source 1200 and the photomask 1400. The light source 1200 may be configured to emit an ultraviolet light; for example, the light source 1200 may be a KrF light source (at 234 nm), an ArF light source (at 193 nm), or an extreme ultraviolet (EUV) light source. In an embodiment, the light source 1200 may be the EUV light source. The light source 1200 may include a single point light source P1, but embodiments of the inventive concept may not be limited thereto. In an embodiment, the light source 1200 may be configured to have a plurality of point light sources.

The photomask 1400 may include image patterns, which are used to transcribe or print the designed layout onto the substrate SUB. The image patterns may be formed, based on layout patterns, which are prepared through layout design and OPC operations described above. The image patterns may be defined by transparent and opaque regions formed on the photomask 1400. The transparent region may be formed by etching the metal layer (e.g., the chromium layer) that is provided on the photomask 1400. The transparent region may be configured to allow light, which is incident from the light source 1200, to propagate toward the substrate SUB. By contrast, the opaque region may be configured to inhibit or prevent the light from propagating toward the substrate SUB.

The light passing through the transparent region of the photomask 1400 may be incident into a photoresist layer, which is formed on the substrate SUB, through the reduction projection apparatus 1600, and as a result, photoresist patterns may be formed on the substrate SUB. The photoresist patterns may have shapes corresponding to the image patterns of the photomask 1400. That is, by using the reduction projection apparatus 1600, it may be possible to form the photoresist patterns, whose shapes are defined by the image patterns of the photomask 1400, on the substrate SUB.

The substrate stage 1800 may be configured to support the substrate SUB. The substrate SUB may include, for example, a silicon wafer. The reduction projection apparatus 1600 may include an aperture. The aperture may be used to control a depth of focus, when the ultraviolet light emitted from the light source 1200 is incident onto the substrate SUB. As an example, the aperture may include a dipole or quadruple aperture. The reduction projection apparatus 1600 may further include a lens for controlling a focal length.

As an integration density of a semiconductor device increases, a distance between the image patterns of the photomask 1400 may be reduced, thereby causing a proximity issue such as undesired interference and diffraction. As a result of the proximity issue, the photoresist patterns formed on the substrate SUB may have distorted shapes (i.e., different from those of the image patterns of the photomask 1400). The distortion of the photoresist patterns may lead to malfunction of an electronic device or circuit to be formed on the substrate SUB.

A resolution enhancement technology may be used to reduce or prevent the distortion of the photoresist patterns. An OPC technology, which is used in the OPC operation S30 of FIG. 2, may be an example of the resolution enhancement technology. According to the OPC technology, the optical distortion issue, which is caused by interference and diffraction, may be quantitatively predicted by a simulation process using an OPC model. The designed layout may be corrected or biased, based on the predicted result. Based on the corrected layout, image patterns may be formed on the photomask 1400, and in the case where the photomask 1400 is manufactured by this method, the photoresist patterns may be formed in desired shapes on the substrate SUB.

A layout of a semiconductor device may include a plurality of layers. In an embodiment, the OPC operation may be performed to correct a layout for each of the layers. In other words, the OPC operation may be independently performed on each of the plurality of layers. A semiconductor device may be manufactured by forming the plurality of layers on a substrate through a semiconductor process. As an example, a semiconductor device may include a plurality of stacked metal layers constituting a specific circuit.

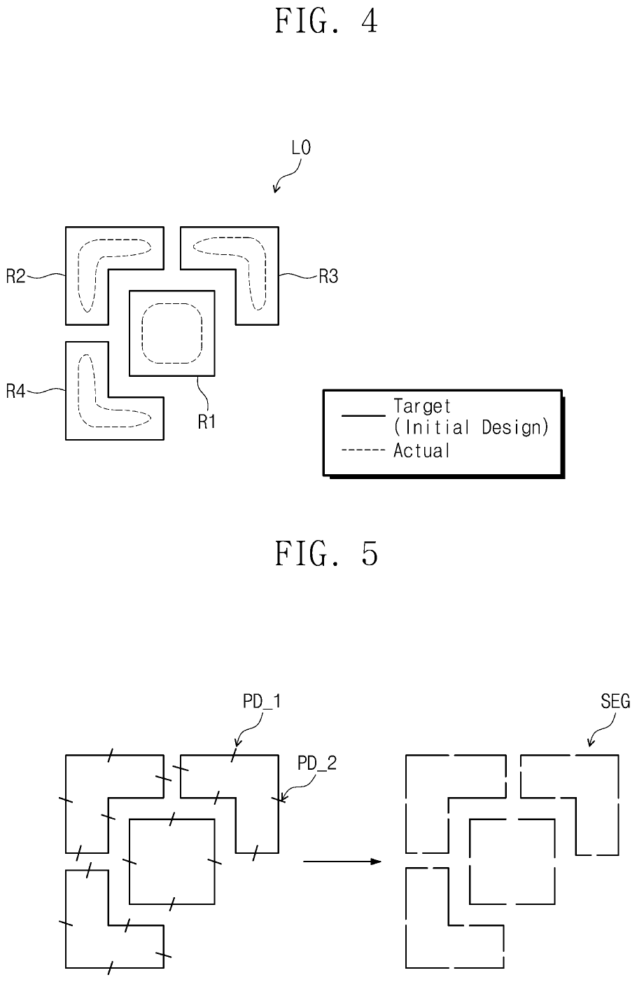

FIG. 4 is a conceptual diagram illustrating a layout according to an embodiment of the inventive concept. In FIG. 4, a solid line depicts target patterns that are desired to be formed on the substrate SUB of FIG. 3, and a dotted line depicts actual patterns that are actually formed on the substrate SUB of FIG. 3.

A designed layout LO may include first to fourth circuit patterns R1, R2, R3, and R4. To reduce complexity in the drawings and to provide better understanding of the inventive concept, an example of a shape of the designed layout LO is illustrated in FIG. 4, but embodiments of the inventive concept are not limited thereto. The designed layout LO may be provided as an initial design layout. The first to fourth circuit patterns R1, R2, R3, and R4, which are depicted by the solid lines in FIG. 4, may illustrate target patterns that are desired to be formed on the substrate SUB.

As described above, owing to the optical distortion issue caused by interference and diffraction, photoresist patterns on the substrate SUB may have shapes different from those in the designed layout LO. For example, even when the image patterns of the photomask 1400 are formed to have shapes depicted by the solid lines of FIG. 4, the first to fourth circuit patterns R1, R2, R3, and R4 to be formed on the substrate SUB may have distorted shapes that are depicted by the dotted lines of FIG. 4. In this case, a circuit formed on the substrate SUB may operate in an abnormal fashion.

An OPC operation may be performed to reduce or prevent the distortion of the patterns. For example, to reduce a difference between the actual pattern (depicted by the dotted line of FIG. 4) and the target pattern (depicted by the solid line of FIG. 4), the designed layout LO may be biased through the OPC operation. The image patterns of the photomask 1400 may be formed based on the biased layout. In the example where the photomask 1400 manufactured through this process is used for a photolithography process, the actual patterns may be formed on the substrate SUB to have substantially the same shapes as those of the first to fourth circuit patterns R1, R2, R3, and R4 defined in the designed layout LO.

FIG. 5 is a conceptual diagram illustrating a process, which is performed to divide a contour of a designed layout of FIG. 4 into a plurality of segments as a part of the OPC operation. Referring to FIG. 5, a plurality of division points may be set on a contour of a designed layout. As an example, a first division point PD_1 and a second division point PD_2 may be set on the contour of the designed layout. One segment SEG may be defined by the first division point PD_1 and the second division point PD_2. The contour of the designed layout may be divided into a plurality of segments in a similar manner based on the division points.

In the present specification, the term “division” may not mean a physical division and may, in some examples, mean identifying one region or portion from another region or portion. Furthermore, although a plurality of segments are illustrated in FIG. 5 as if they were physically spaced apart from each other, FIG. 5 is a schematic diagram that is presented for the purpose of providing better understanding of embodiments of the inventive concept.

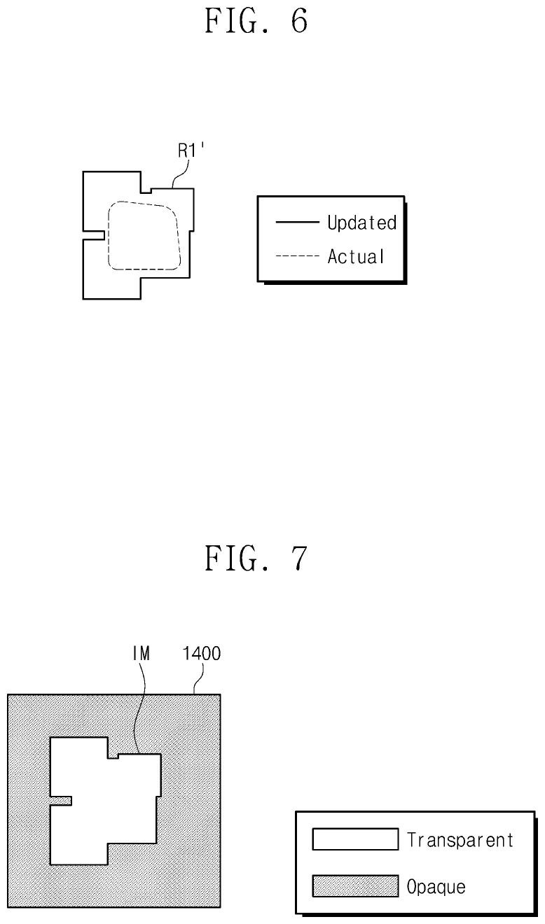

In the OPC operation, each of the divided segments SEG may be a unit object to which the biasing can be applied. Each of the divided segments SEG may be independently biased. For example, one of the segments SEG may be biased in one of a first direction (e.g., a positive or outward direction) and a second direction (e.g., a negative or inward direction), independent of the other ones of the segments SEG. Each of the divided segments SEG may be biased to reduce a difference in shape or size between the actual and target patterns. The biasing of the divided segments SEG may be performed by the OPC tool 34 of FIG. 1. An example of a corrected layout, which is obtained based on the biased segments, is illustrated in FIG. 6.

FIG. 6 is a conceptual diagram illustrating a layout corrected by the OPC operation of FIG. 5. Referring to FIG. 6, the corrected layout may include a first correction pattern R1′ that is corrected from the first circuit pattern R1 of FIG. 4. For convenience in illustration, the second to fourth circuit patterns R2, R3, and R4 of FIG. 4 are omitted from FIG. 6. As previously described with reference to FIG. 5, the contour of the first circuit pattern R1 of FIG. 4 may be divided into a plurality of segments, and each of the divided segments may be biased. As illustrated in FIG. 6, each of the segments may be biased in one of the first direction (e.g., the positive or outward direction) and the second direction (e.g., the negative or inward direction). In an embodiment, at least one of the segments may not be biased. FIG. 6 show an example of the first correction pattern R1′ that is obtained as a result of the biasing.

The dotted line of FIG. 6 depicts an actual pattern, which will be formed on the substrate SUB of FIG. 3 when the corrected layout is used. By biasing each of the divided segments, it may be possible to reduce a difference between the actual pattern and the target pattern.

FIG. 7 is a conceptual diagram illustrating a photomask manufactured based on the corrected layout of FIG. 6. A mask rule check (MRC) operation may be performed on the corrected layout of FIG. 6, and then, mask data may be generated. A photomask may be manufactured, based on the mask data.

As an example, referring to FIG. 7, the photomask 1400 may include an image pattern IM corresponding to the first correction pattern R1′ of FIG. 6. The photomask 1400 may include a transparent region and an opaque region. The opaque region may be configured to reduce or prevent light from passing therethrough. By contrast, the transparent region may be configured to allow light, which is emitted from the light source 1200 of FIG. 3, to pass therethrough. Light passing through the photomask 1400 may be incident into a photoresist layer on the substrate SUB of FIG. 3. For example, in the example where a negative photoresist layer is used for the photolithography process, the image pattern IM may be the transparent region.

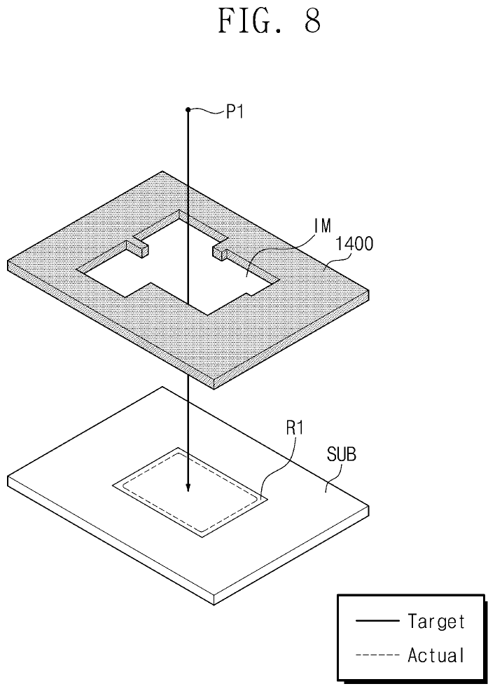

FIG. 8 is a conceptual diagram illustrating a photolithography process of printing a circuit pattern on a substrate, using the photomask of FIG. 7. A point light source P1 in the light source 1200 of FIG. 3 may be configured to emit light toward the photomask 1400. In an exposure operation, the emitted light may pass through the transparent region of the image pattern IM and then may be incident into the negative photoresist layer on the substrate SUB. A region of the negative photoresist layer, which is exposed to the light, may be left, and another region of the negative photoresist layer, which is not exposed to the light, may be removed, in a subsequent developing step. Accordingly, the first circuit pattern R1 corresponding to the image pattern IM may be formed on the substrate SUB.

An actual pattern printed on the substrate SUB may have a shape depicted by the dotted line. The actual pattern may have substantially the same shape and size as those of the target pattern depicted by the solid line. That is, by using the afore-described OPC operation, it may be possible to reduce a difference between the actual and target patterns.

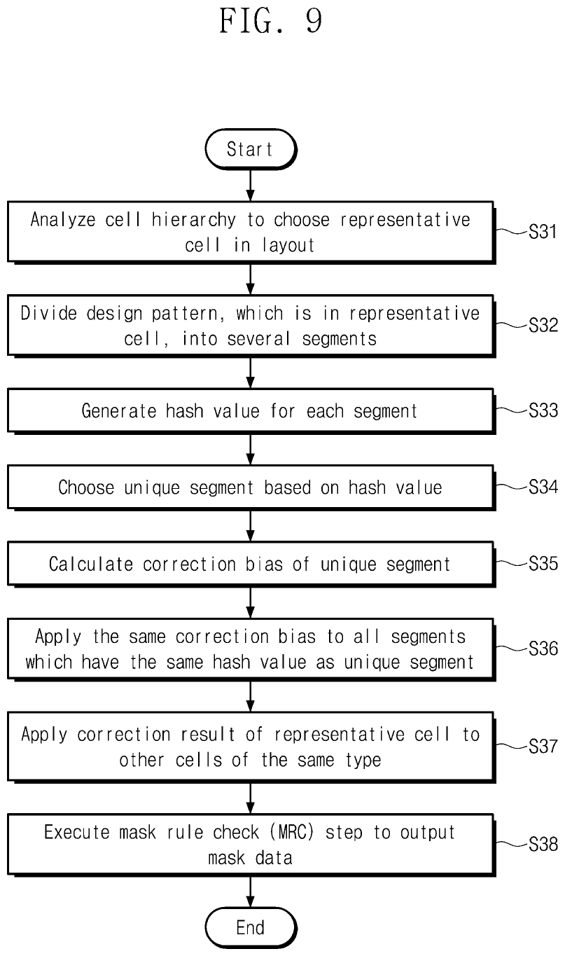

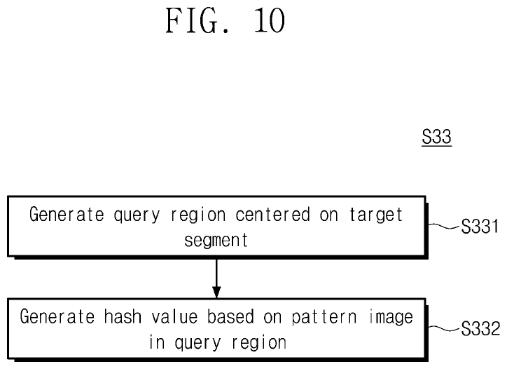

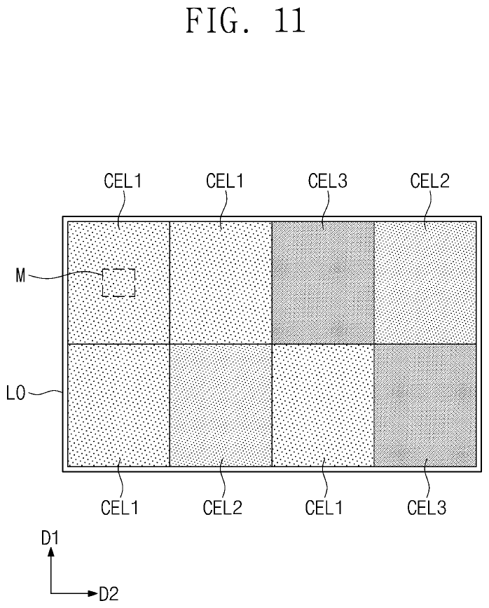

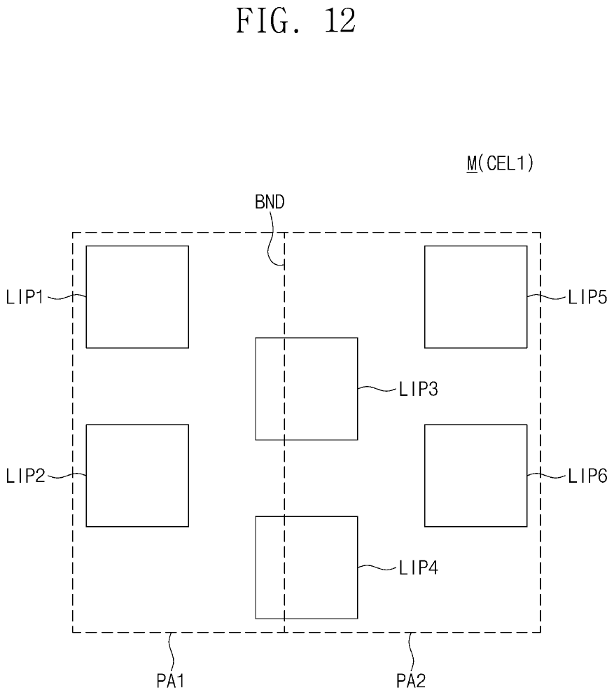

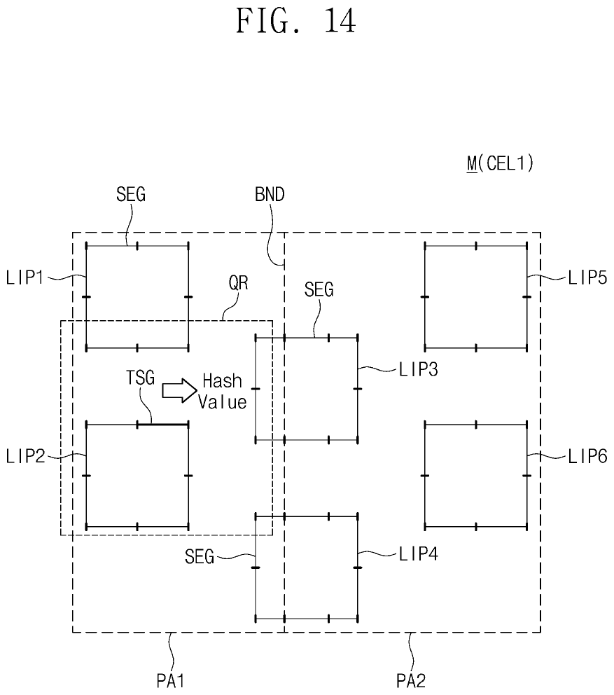

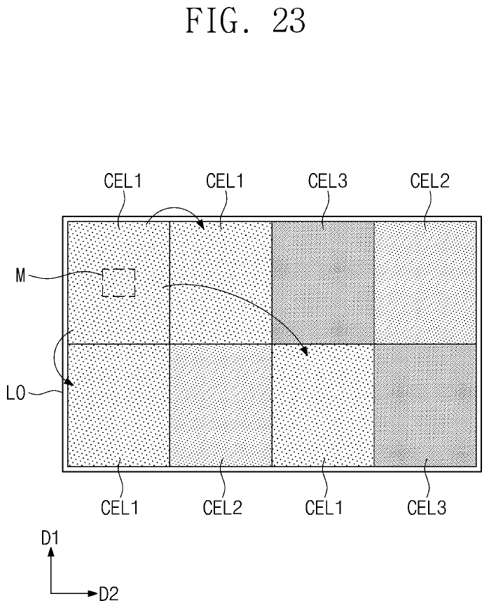

FIG. 9 is a flow chart schematically illustrating a detailed process of an OPC operation according to an embodiment of the inventive concept. FIG. 10 is a flow chart illustrating a process of generating a hash value of a segment according to an embodiment of the inventive concept. FIGS. 11 and 23 are plan views each illustrating an example of a designed layout according to an embodiment of the inventive concept. FIGS. 12 to 22 are plan views of a portion ‘M’ of FIG. 11 that illustrate an OPC operation according to an embodiment of the inventive concept.

Referring to FIGS. 9 and 11, a layout LO, which is generated through the layout design process S20 previously described with reference to FIG. 2, may be provided. The layout LO may be a layout of a single layer.

According to an embodiment of the inventive concept, the layout LO may contain information on a cell hierarchy. For example, the layout LO may be a layout of a memory device. In general, the layout LO may contain information on the cell hierarchy for the memory device, in which unit memory cells are repeatedly arranged. According to the cell hierarchy, the layout LO may include a plurality of cells CEL as illustrated in FIG. 11.

A representative cell may be chosen from the layout LO by analyzing the cell hierarchy (S31). In detail, the layout LO of FIG. 11 may include first cells CEL1, second cells CEL2, and third cells CEL3. The first cells CEL1 may be of the same type. The second cells CEL2 may be of the same type. The third cells CEL3 may be of the same type. One first cell CEL1, which is chosen from the first cells CEL1 of the same type, may be used as the representative cell. One second cell CEL2, which is chosen from the second cells CEL2 of the same type, may be used as the representative cell. One third cell CEL3, which is chosen from the third cells CEL3 of the same type, may be used as the representative cell.

Hereinafter, the optical proximity correction process will be described with reference to an example, in which the first cell CEL1 placed at the top left of FIG. 11 is chosen as the representative cell. Referring to FIGS. 9 and 12, a portion ‘M’ of the first cell CEL1, which is the representative cell, may include a first patch PA1 and a second patch PA2, which are adjacent to each other. A patch boundary BND may exist between the first patch PA1 and the second patch PA2.

In detail, the layout of the first cell CEL1 may be divided into a plurality of patches PA by using the OPC tool 34 of FIG. 1. As an example, the OPC tool 34 may analyze the cell hierarchy from layout design data. Next, the first cell CEL1 may be divided into the patches PA in consideration of the type of unit device and the proximity environment. The patches PA may be provided to respective nodes of the OPC tool 34. The OPC process on the patches PA may be executed in the nodes of the OPC tool 34 in a parallel manner. Each of the patches PA may be a unit structure, on which the optical proximity correction process is executed.

The portion ‘M’ of the first cell CEL1 may include a plurality of design patterns LIP1 to LIP6. As an example, the design patterns LIP1 to LIP6 may correspond to the circuit patterns R1 to R4 previously described with reference to FIG. 4. In the present embodiment, each of the design patterns LIP1 to LIP6 may be an island pattern. For example, each of the design patterns LIP1 to LIP6 may have a rectangular or tetragonal shape. The design patterns LIP1 to LIP6 may include first to sixth design patterns LIP1 to LIP6. The first to sixth design patterns LIP1 to LIP6 may be arranged in a zigzag shape. The third and fourth design patterns LIP3 and LIP4 may be placed on the patch boundary BND.

A data preparation operation may be executed on the representative cell CEL1 including the first to sixth design patterns LIP1 to LIP6. The data preparation step may include performing an optical proximity correction (OPC) step on a designed layout (FIG. 2; S30) and performing a mask rule check (MRC) step on the result of the OPC step (S38).

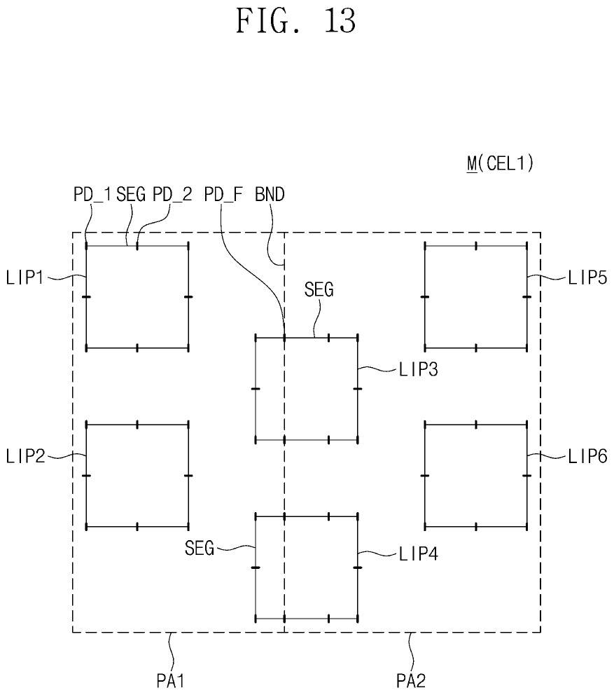

Referring to FIGS. 9 and 13, each of the first to sixth design patterns LIP1 to LIP6 may be divided into a plurality of segments SEG (S32). A plurality of division points PD may be created on a contour of each of the first to sixth design patterns LIP1 to LIP6. For example, a first division point PD_1 and a second division point PD_2 may be created on the contour of the first design pattern LIP1.

The contour may be divided into a plurality of segments SEG, based on the division points PD. In an embodiment, the design pattern LIP1 to LIP6 may be divided into the segments SEG in the same manner as described with reference to FIG. 5. For example, the segment SEG may be created in the contour of the first design pattern LIP1 by the first division point PD_1 and the second division point PD_2.

The division points PD on the first, second, fifth, and sixth design patterns LIP1, LIP2, LIP5, and LIP6 may be created with a specific distance. Thus, segments SEG with the same length may be created in the first, second, fifth, and sixth design patterns LIP1, LIP2, LIP5, and LIP6. By contrast, segments SEG with different lengths may be created in the third and fourth design patterns LIP3 and LIP4. This may be because additional division point PD_F are created at points of the contour that intersect the patch boundary BND.

Referring to FIGS. 9, 10, and 14, a hash value may be generated for each of the segments SEG (S33). In detail, a hash value may be generated for one of the segments SEG (i.e., a target segment TSG). A query region QR may be generated to be centered on the target segment TSG (S331). For example, the query region QR may be a peripheral region where optical influence on the target segment TSG cannot be disregarded. The target segment TSG as well as some of the segments SEG, which are placed near the target segment TSG, may exist in the query region QR.

A hash value may be generated based on a pattern image in the query region QR (S332). The pattern image may include a shape of the target segment TSG, a shape of a neighboring segment SEG, and a distance between the target segment TSG and the neighboring segment SEG. In other words, the hash value of the target segment TSG may reflect information on the shape of the target segment TSG, the shape of the neighboring segment SEG, and the distance between the target segment TSG and the neighboring segment SEG. The hash value of the target segment TSG may be generated as a unique 64-bit value. The hash value of the target segment TSG may be a hash ID of the target segment TSG.

The hash value for each of the segments SEG may be generated by choosing each of the segments SEG as a target segment based on the afore-described method.

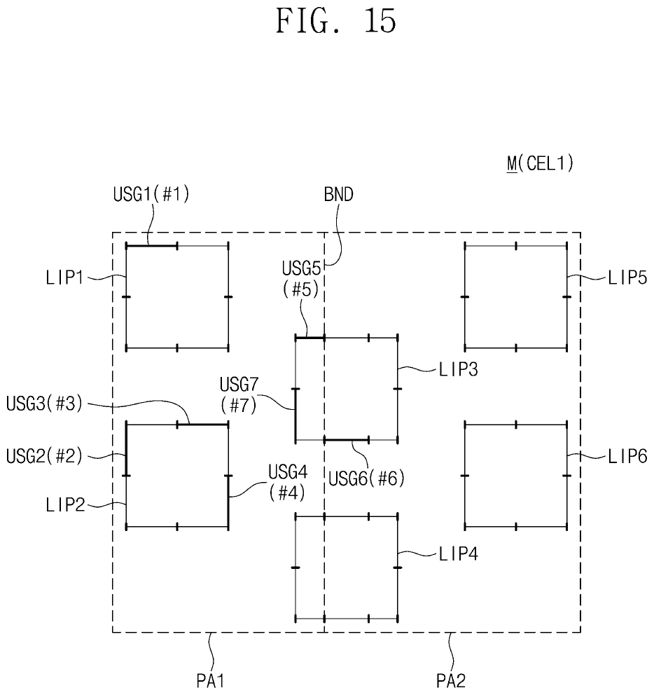

Referring to FIGS. 9 and 15, a unique segment USG may be chosen from the segments SEG, based on the hash value (S34). If the segments SEG have the same hash value, they may be classified as the same segment. A representative one of the segments SEG with the same hash value may be chosen as the unique segment USG.

FIG. 15 illustrates an example, in which seven unique segments USG are chosen from the segments SEG constituting the first to sixth design patterns LIP1 to LIP6. The unique segments USG of FIG. 15 may include first to seventh unique segments USG1 to USG7. The first to seventh unique segments USG1 to USG7 may have first to seventh hash values (#1-#7), which are different from each other.

As an example, the fifth unique segment USG5 may be adjacent to the patch boundary BND. Owing to the patch boundary BND, the fifth unique segment USG5 may have a length different from the first unique segment USG1, and thus, the fifth unique segment USG5 may have a hash value different from the first unique segment USG1.

For example, the seventh unique segment USG7 may include a segment of a short length, like the fifth unique segment USG5 in the query region, and thus, the seventh unique segment USG7 may have a hash value different from the second unique segment USG2.

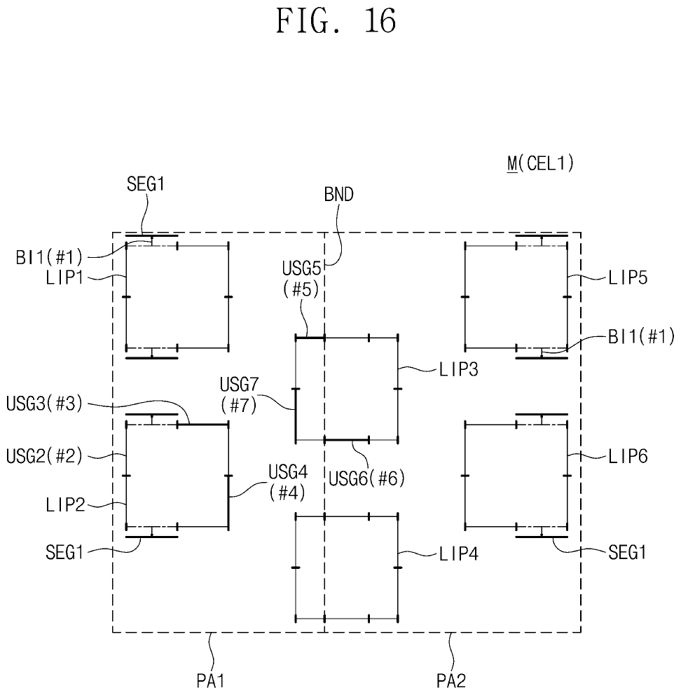

Referring to FIGS. 9 and 16, a first bias BI1, which will be applied to the first unique segment USG1, may be calculated using the OPC tool 34 of FIG. 1 (S35). According to an embodiment of the inventive concept, when the OPC step is executed using the OPC tool 34 of FIG. 1, the same correction bias may be applied to segments SEG with the same hash value (S36).

The first bias BI1 may be commonly applied to first segments SEG1, which have the same hash value (i.e., the first hash value (#1))) as the first unique segment USG1. In this case, the first segments SEG1 may be biased or shifted in a first direction DI by the first bias BI1.

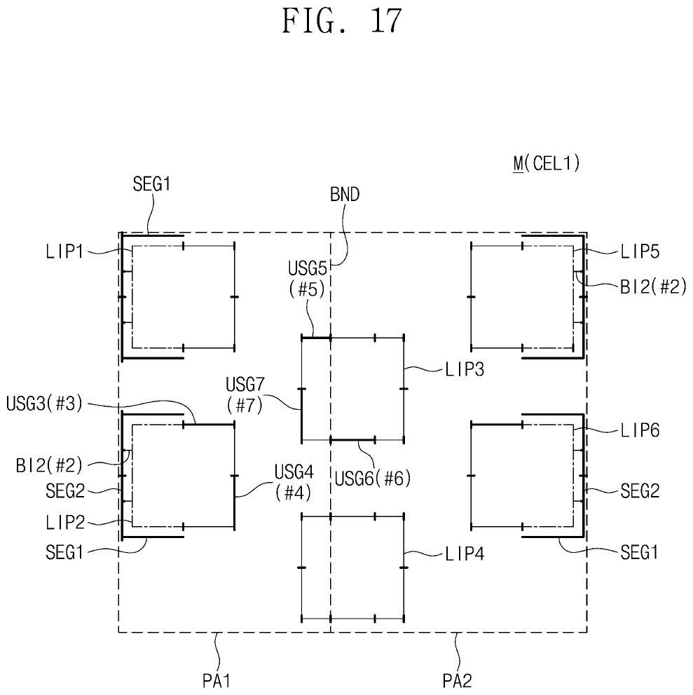

Referring to FIGS. 9 and 17, a second bias BI2, which will be applied to the second unique segment USG2, may be calculated using the OPC tool 34 of FIG. 1 (S35). The second bias BI2 may be commonly applied to second segments SEG2, which have the same hash value (i.e., the second hash value (#2)) as the second unique segment USG2 (S36). Thus, the second segments SEG2 may be biased or shifted in a second direction D2 by the second bias BI2.

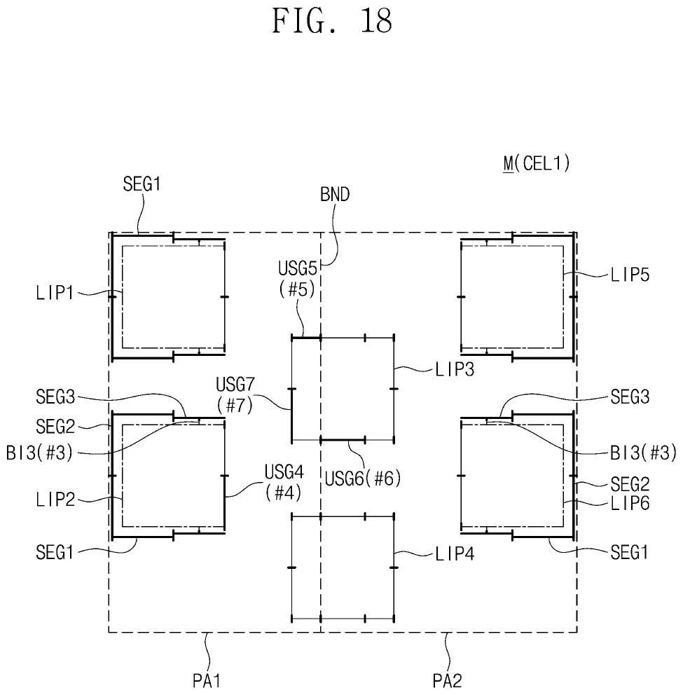

Referring to FIGS. 9 and 18, a third bias BI3, which will be applied to the third unique segment USG3, may be calculated using the OPC tool 34 of FIG. 1 (S35). The third bias BI3 may be commonly applied to third segments SEG3, which have the same hash value (i.e., the third hash value (#3)) as the third unique segment USG3 (in S36). Thus, the third segments SEG3 may be biased or shifted in the first direction DI by the third bias BI3. In an embodiment, the third bias BI3 may be smaller than the first bias BI1 of FIG. 16.

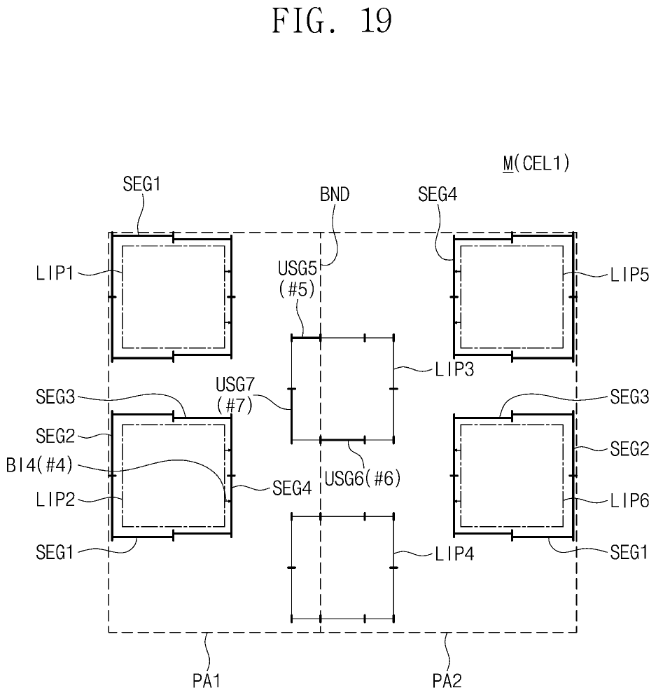

Referring to FIGS. 9 and 19, a fourth bias BI4, which will be applied to the fourth unique segment USG4, may be calculated using the OPC tool 34 of FIG. 1 (S35). The fourth bias BI4 may be commonly applied to fourth segments SEG4, which have the same hash value (i.e., the fourth hash value (#4)) as the fourth unique segment USG4 (in S36). Thus, the fourth segments SEG4 may be biased or shifted in the second direction D2 by the fourth bias BI4. In an embodiment, the fourth bias BI4 may be smaller than the second bias BI2 of FIG. 17.

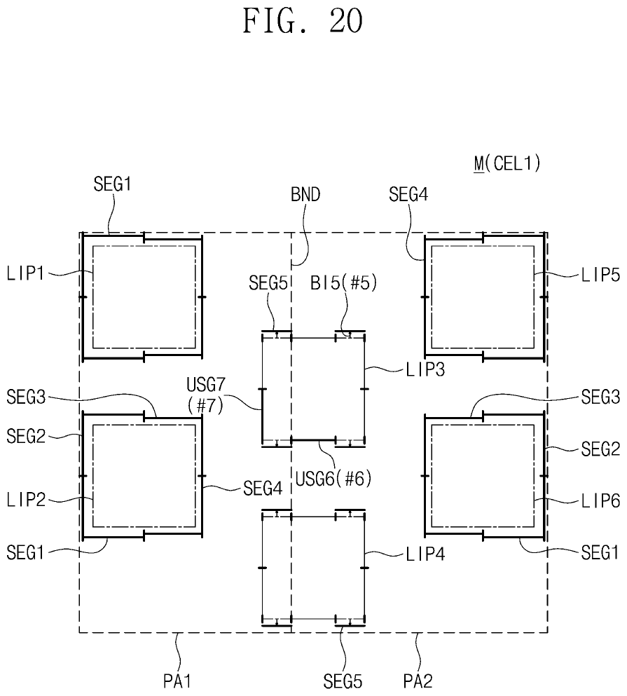

Referring to FIGS. 9 and 20, a fifth bias BI5, which will be applied to the fifth unique segment USG5, may be calculated using the OPC tool 34 of FIG. 1 (S35). The fifth bias BI5 may be commonly applied to fifth segments SEG5, which have the same hash value (i.e., the fifth hash value (#5)) as the fifth unique segment USG5 (S36). Thus, the fifth segments SEG5 may be biased or shifted in the first direction DI by the fifth bias BI5.

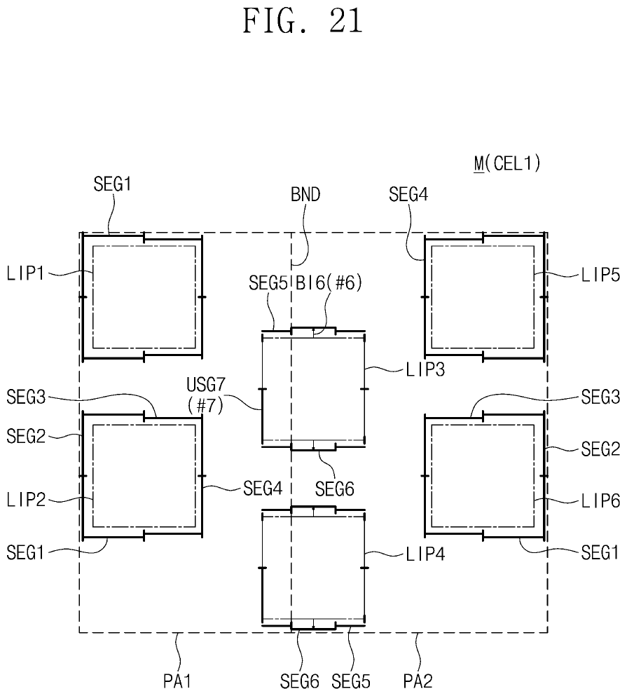

Referring to FIGS. 9 and 21, a sixth bias BI6, which will be applied to the sixth unique segment USG6, may be calculated using the OPC tool 34 of FIG. 1 (S35). The sixth bias BI6 may be commonly applied to sixth segments SEG6, which have the same hash value (i.e., the sixth hash value (#6)) as the sixth unique segment USG6 (S36). Thus, the sixth segments SEG6 may be biased or shifted in the first direction DI by the sixth bias BI6. In an embodiment, the sixth bias BI6 may be greater than the fifth bias BI5 of FIG. 20.

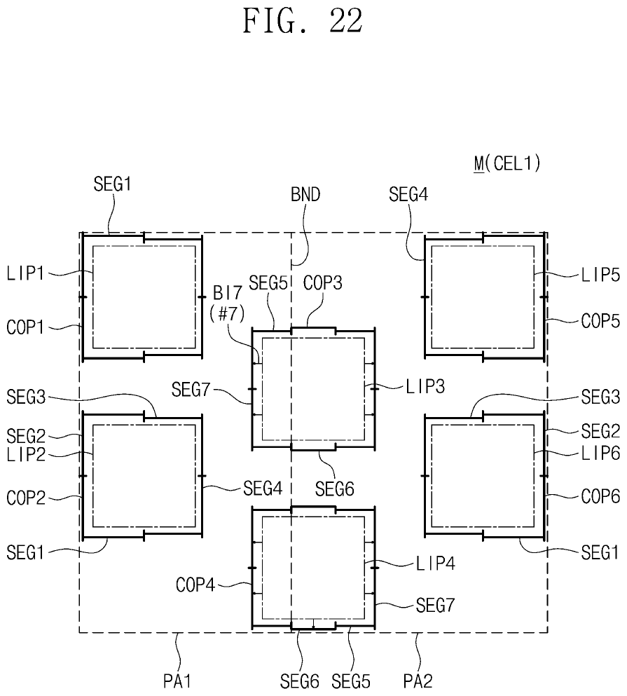

Referring to FIGS. 9 and 22, a seventh bias BI7, which will be applied to the seventh unique segment USG7, may be calculated using the OPC tool 34 of FIG. 1 (S35). The seventh bias BI7 may be commonly applied to seventh segments SEG7, which have the same hash value (i.e., the seventh hash value (#7)) as the seventh unique segment USG7 (S36). Thus, the seventh segments SEG7 may be biased or shifted in the second direction D2 by the seventh bias BI7.

A correction bias may be applied to all of the segments SEG through the afore-described processes. In embodiments of the inventive concept, the correction bias may not be independently calculated for and applied to each of the segments SEG. If each of the segments SEG is independently corrected, the execution time for the OPC step may be excessively increased. According to an embodiment of the inventive concept, a correction bias may be obtained for the unique segment USG, and then, the obtained correction bias may be applied to all of the segments SEG that have the same hash value. Thus, the execution time for the OPC step may be significantly reduced.

The corrected segments SEG may constitute a correction pattern COP. For example, first to sixth correction patterns COP1 to COP6 may be generated by applying an OPC operation to the first to sixth design patterns LIP1 to LIP6. The OPC operation on the first cell CEL1, which serves as the representative cell, may be completed through the operations previously described with reference to FIGS. 12 to 22. In an embodiment, the portion ‘M’ in the first cell CEL1 may include the first to sixth correction patterns COP1 to COP6 generated by the afore-described method.

Referring to FIGS. 9 and 23, a correction result of the first cell CEL1, which serves as the representative cell, may be applied to the other ones of the first cells CEL1 in the same manner (S37). Thus, by performing the OPC operation on just one representative cell CEL1, the OPC operation on the other ones of the first cells CEL1 may be automatically completed. The information on the first cells CEL1 or on whether a specific cell is of the same type of the first cell CEL1 may be obtained from the cell hierarchy, as described above.

The OPC operation on the second cells CEL2 in the layout LO may be performed in the same manner as the afore-described OPC step on the first cells CEL1. The OPC operation on the third cells CEL3 in the layout LO may be performed in the same manner as the afore-described OPC step on the first cells CEL1.

If the correction patterns COP are respectively generated for design patterns LIP in the layout LO, the mask rule check (MRC) step may be executed on the generated correction patterns COP (S38 of FIG. 9). The correction patterns COP may be additionally corrected through the MRC operation, and all errors violating a given mask rule may be removed. Accordingly, the data preparation operation may be finished, and the final result may be output as mask data.

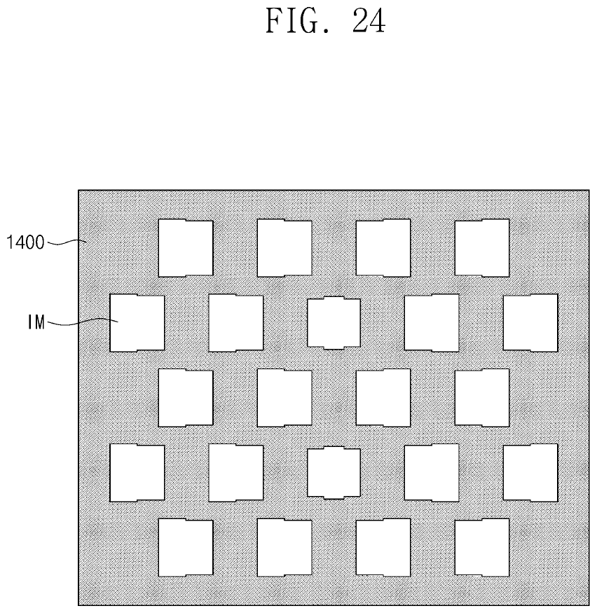

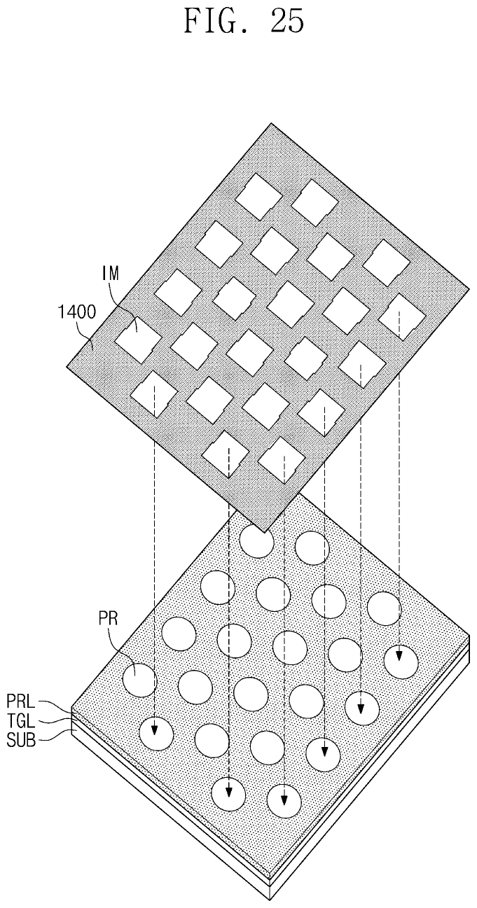

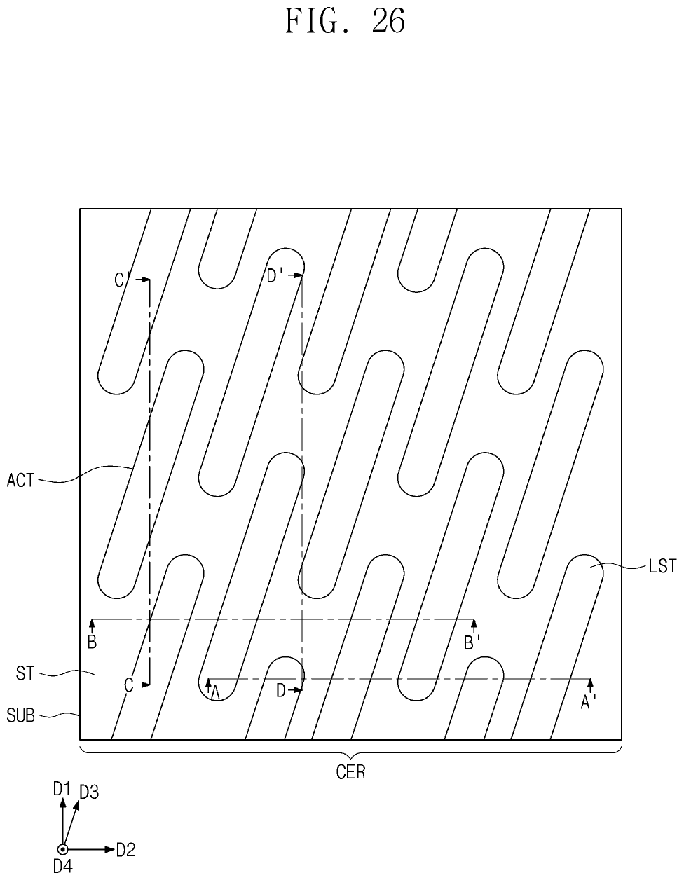

FIG. 24 is a plan view illustrating a photomask according to an embodiment of the inventive concept. Referring to FIGS. 2 and 15, the photomask 1400 may be manufactured based on the final results of the correction patterns COP (e.g., the first to sixth correction patterns COP1 to COP6 of FIG. 22) (S40 of FIG. 2). The photomask 1400 may include image patterns IM. The image patterns IM may be formed based on the afore-described correction patterns in the first cells CEL1 of FIG. 23.

FIG. 25 is a conceptual diagram illustrating a process of forming photoresist patterns on a substrate using the photomask of FIG. 24. Referring to FIG. 25, the light source 1200 of FIG. 3 may be configured to emit light to the photomask 1400. The emitted light may pass through the transparent region of the image patterns IM and may be provided to a photoresist layer PRL on the substrate SUB (e.g., through an exposure process). A region of the photoresist layer PRL onto which the light is irradiated may become a photoresist pattern PRP. The photoresist patterns PRP may be formed to have a shape and size similar to the design patterns LIP that were previously described with reference to FIG. 12.

In a subsequent developing process, all regions of the photoresist layer PRL other than the photoresist patterns PRP may be removed, and the photoresist patterns PRP may be left. An etch target layer TGL on the substrate SUB may be patterned using the left photoresist patterns PRP as an etch mask. Thus, desired target patterns may be formed on the substrate SUB. By forming target patterns in each layer using this method, it may be possible to manufacture a semiconductor device (S50 of FIG. 2).

In the OPC operation described with reference to FIGS. 9 to 23, by using information on the cell hierarchy, a result of the OPC operation on a representative cell may be applied to all of the remaining cells in the same manner. Thus, the execution time for the OPC operation may be significantly reduced.

Furthermore, even in the OPC step on the representative cell, a unique segment may be chosen, based on hash values of the segments. A correction bias may be generated for the unique segment. The correction bias may be applied to the remaining ones of the segments that have the same hash value as the unique segment. Thus, it may be possible to maintain the consistency of the OPC operation, increase the accuracy of the OPC operation, and reduce the execution time for the OPC operation.

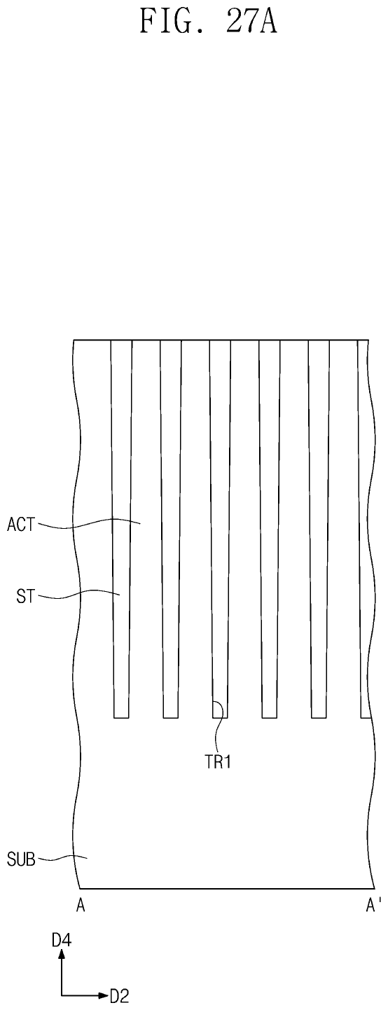

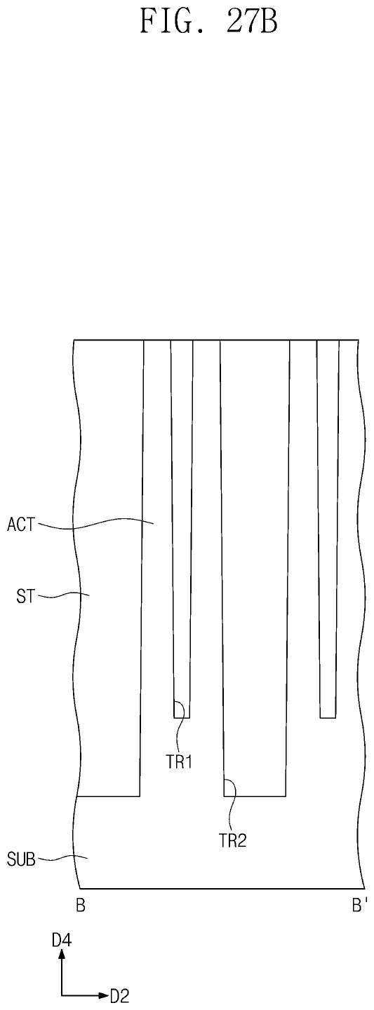

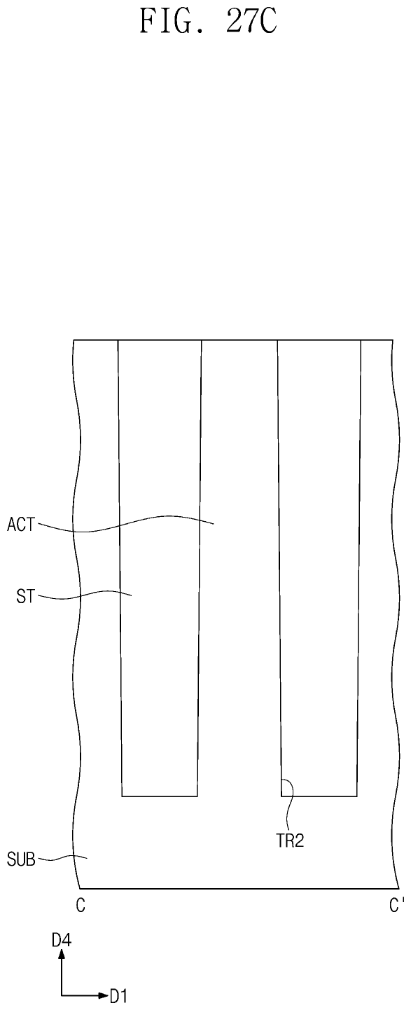

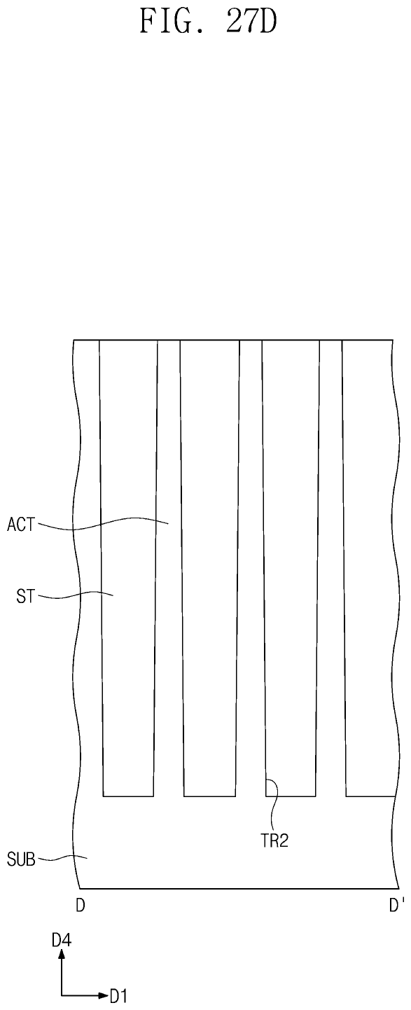

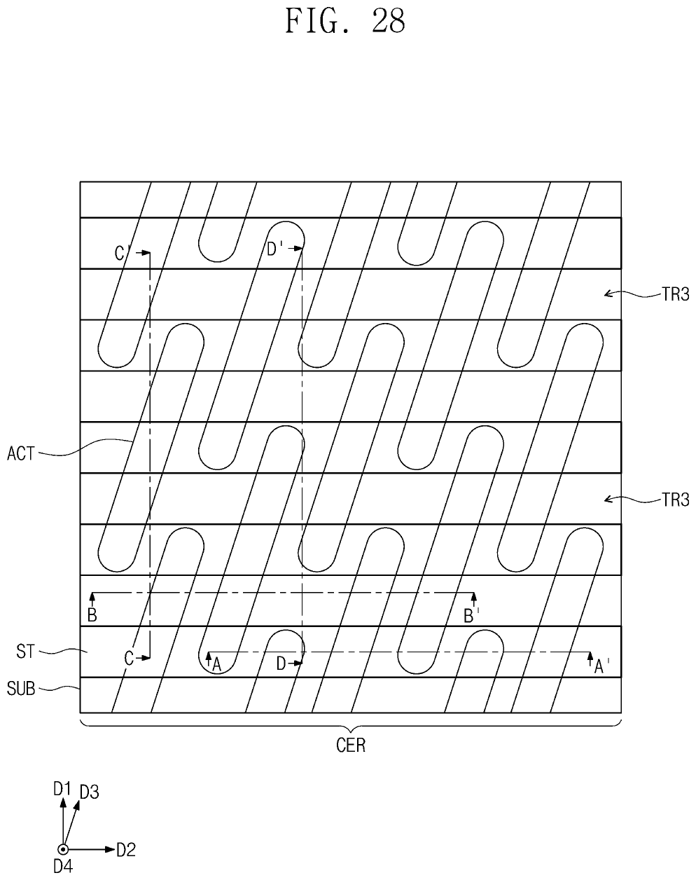

FIGS. 26, 28, 30, 32, 34, 36, 38, and 40 are plan views illustrating a method of fabricating a semiconductor device according to an embodiment of the inventive concept. FIGS. 27A, 29A, 31A, 33A, 35A, 37A, 39A, and 41A are sectional views taken along lines A-A′ of FIGS. 26, 28, 30, 32, 34, 36, 38, and 40, respectively. FIGS. 27B, 29B, 31B, 33B, 35B, 37B, 39B, and 41B are sectional views taken along lines B-B′ of FIGS. 26, 28, 30, 32, 34, 36, 38, and 40, respectively. FIGS. 27C, 29C, 31C, 33C, 35C, 37C, 39C, and 41C are sectional views taken along lines C-C′ of FIGS. 26, 28, 30, 32, 34, 36, 38 and 40, respectively. FIGS. 27D, 29D, 31D, 33D, 35D, 37D, 39D, and 41D are sectional views taken along lines D-D′ of FIGS. 26, 28, 30, 32, 34, 36, 38 and 40, respectively.

Referring to FIGS. 26 and 27A to 27D, active patterns ACT may be formed by patterning an upper portion of a substrate SUB. Each of the active patterns ACT may be extended in a third direction D3, which is parallel to a top surface of the substrate SUB. The active patterns ACT may be two-dimensionally arranged in a first direction D1 and a second direction D2. The active patterns ACT may be spaced apart from each other in the third direction D3.

The active patterns ACT may be realized using a photolithography process. A photomask, which is used in the photolithography process for realizing the active patterns ACT, may be manufactured through the OPC method described with reference to FIGS. 9 to 23.

In an embodiment, the patterning process to form the active patterns ACT may include an EUV lithography process. The EUV lithography process may include performing an exposing process of irradiating the EUV light onto a photoresist layer and performing a developing process of developing the photoresist layer. As an example, the photoresist layer may be an organic photoresist layer containing an organic polymer (e.g., polyhydroxystyrene). The organic photoresist layer may further include a photosensitive compound which can be reacted with the EUV light. The organic photoresist layer may further contain a material having high EUV absorptivity (e.g., organometallic materials, iodine-containing materials, or fluorine-containing materials). As another example, the photoresist layer may be an inorganic photoresist layer containing an inorganic material (e.g., tin oxide).

The photoresist layer may be formed to have a relatively small thickness. Photoresist patterns may be formed by developing the photoresist layer, which is exposed to the EUV light. When viewed in a plan view, the photoresist patterns may be formed to have a line shape extending in a specific direction, an island shape, a zigzag shape, a honeycomb shape, or a circular shape, but embodiments of the inventive concept are not limited to these examples.

Mask patterns may be formed by patterning at least one layer, which is disposed below the photoresist patterns, using the photoresist patterns as an etch mask. Desired patterns may be formed on a wafer by patterning a target layer using the mask patterns as an etch mask.

For example, the minimum pitch between the active patterns ACT, which are realized by the EUV lithography process according to the present embodiment, may be less than or equal to 45 nm. In other words, by using the EUV lithography process, it may be possible to form the active patterns ACT precisely and finely with just one photomask.

First and second trenches TRI and TR2 may be defined between the active patterns ACT. The first trench TR1 may be defined between a pair of active patterns ACT, which are adjacent to each other in the second direction D2. The second trench TR2 may be defined between a pair of active patterns ACT, which are adjacent to each other in the third direction D3.

In some embodiments, a device isolation layer ST may be formed to at least partially fill the first and second trenches TRI and TR2. In some embodiments, the device isolation layer ST may be formed to completely fill the first and second trenches TRI and TR2 and to at least partially cover the active patterns ACT. A planarization process may be performed on the device isolation layer ST to expose the top surfaces of the active patterns ACT.

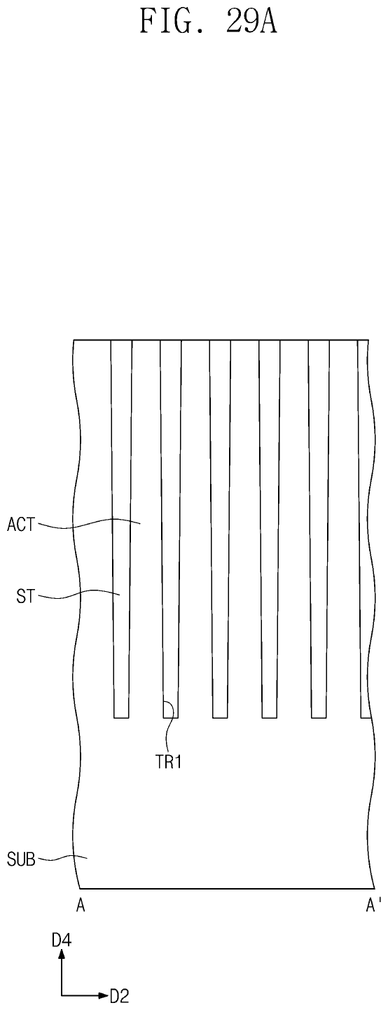

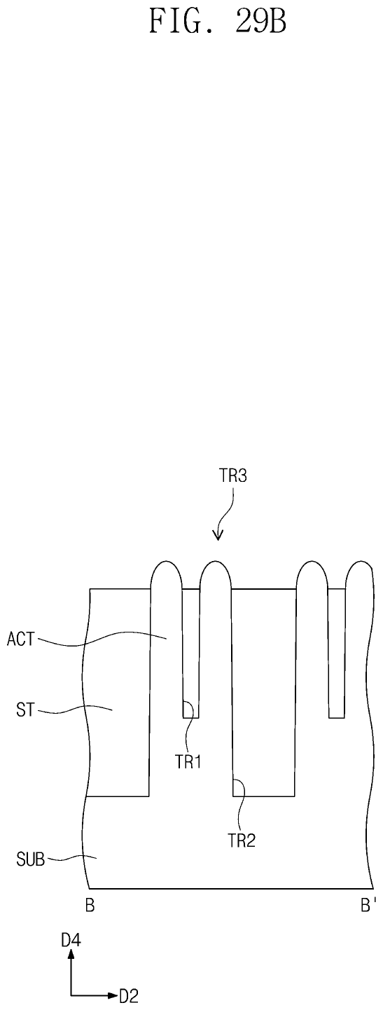

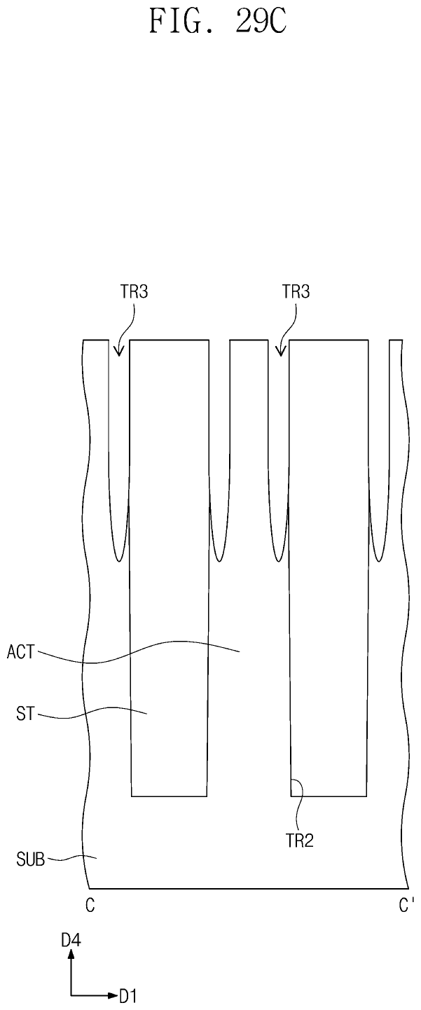

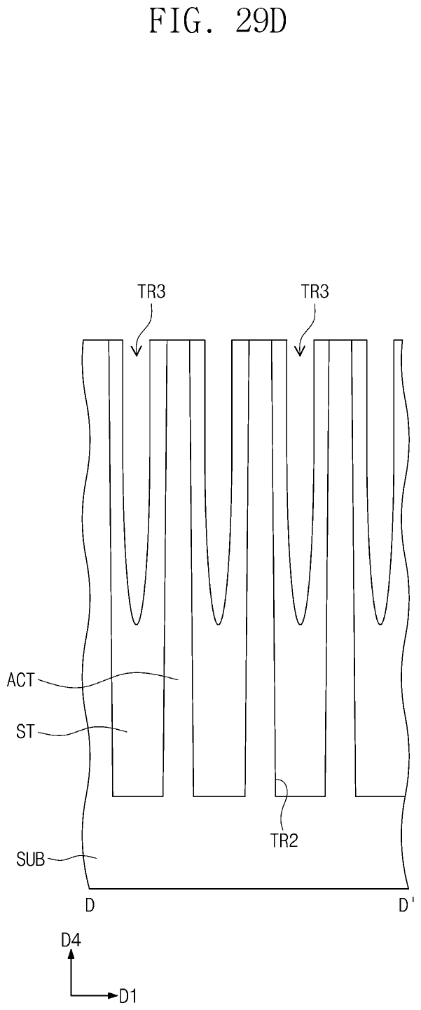

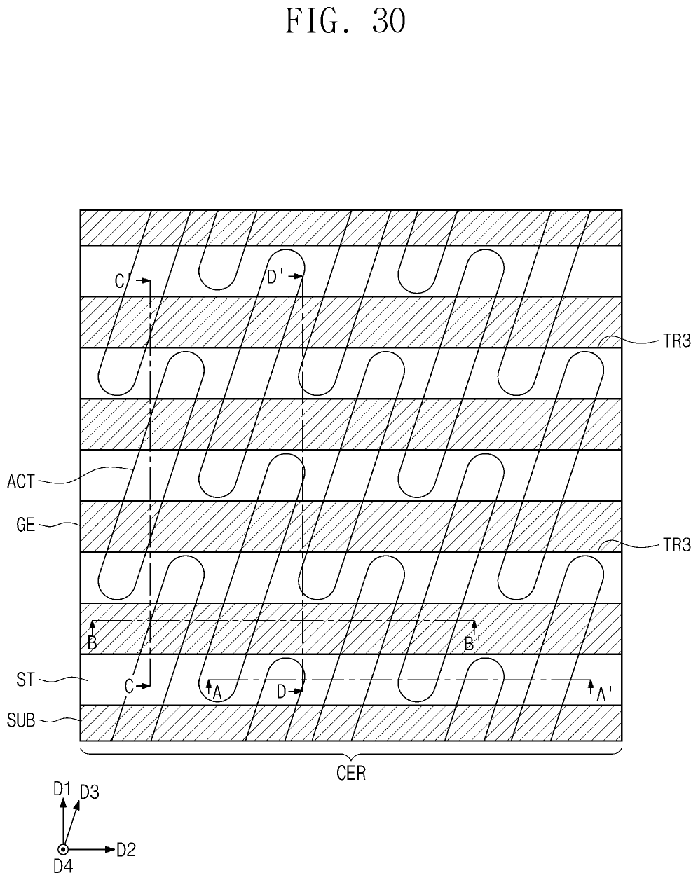

Referring to FIGS. 28 and 29A to 29D, third trenches TR3 may be formed by patterning the active patterns ACT and the device isolation layer ST. When viewed in a plan view, each of the third trenches TR3 may have a line shape extending in the second direction D2.

The formation of the third trenches TR3 may include forming a hard mask pattern with openings and etching the exposed portions of the active patterns ACT and the device isolation layer ST using the hard mask pattern as an etch mask. The third trench TR3 may be formed to be shallower than the first trench TR1.

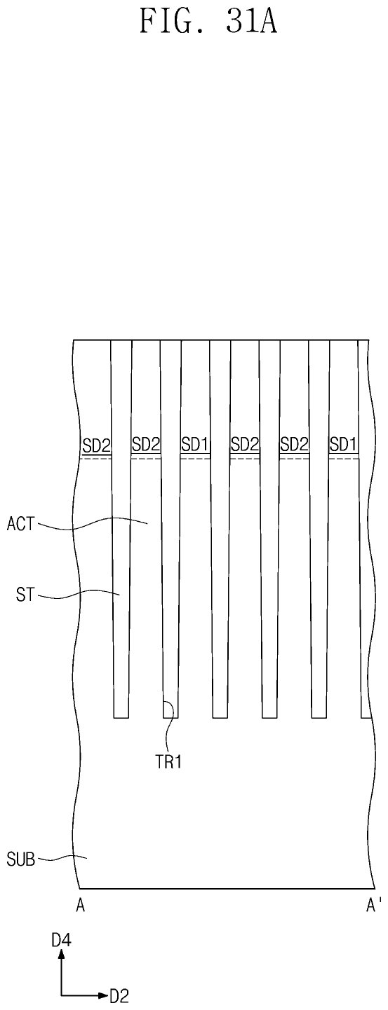

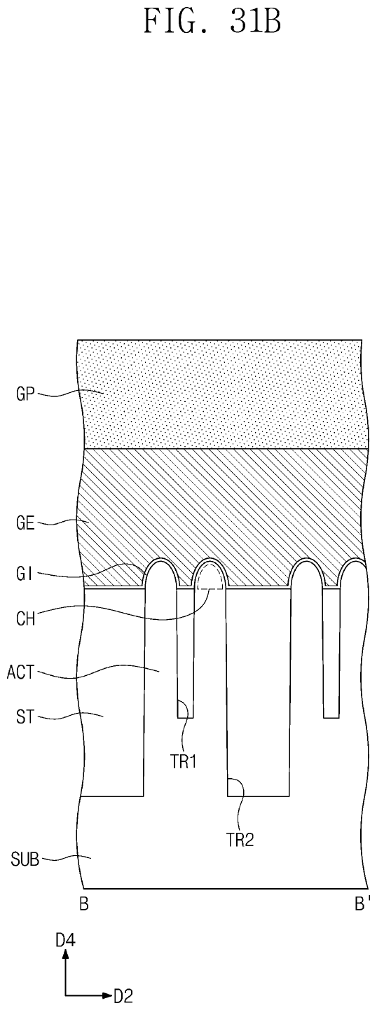

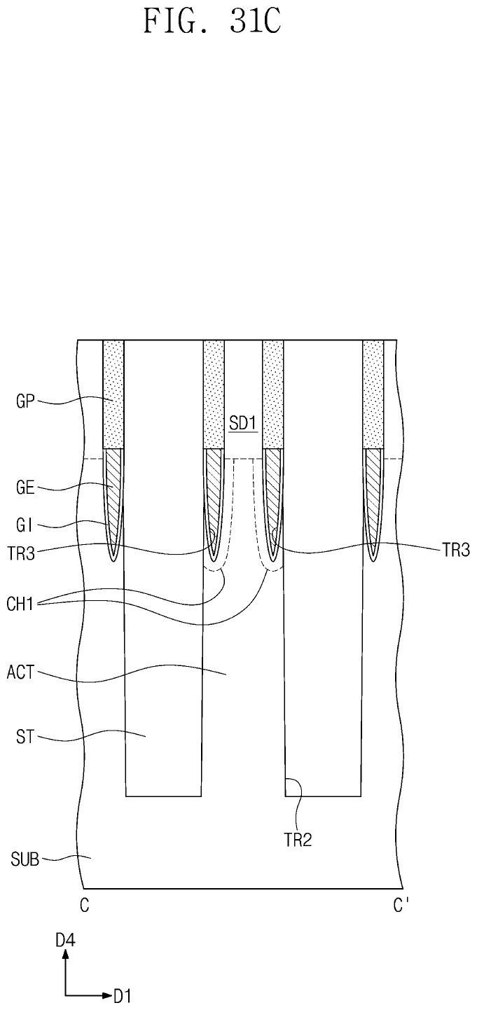

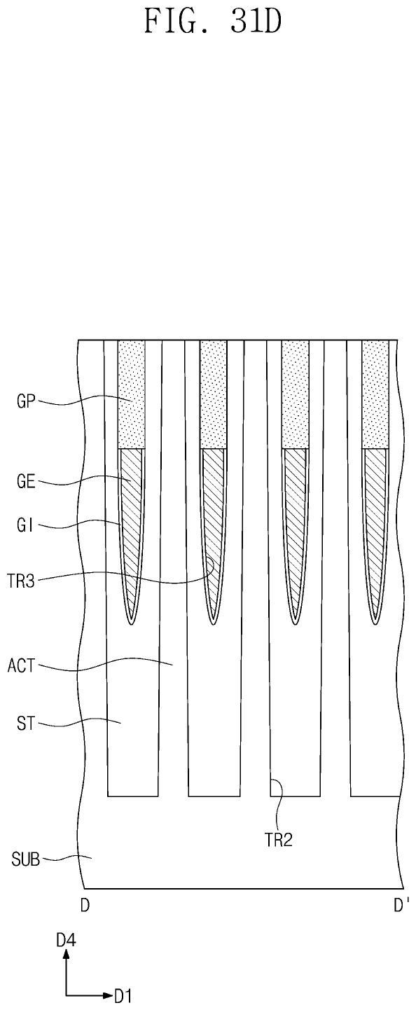

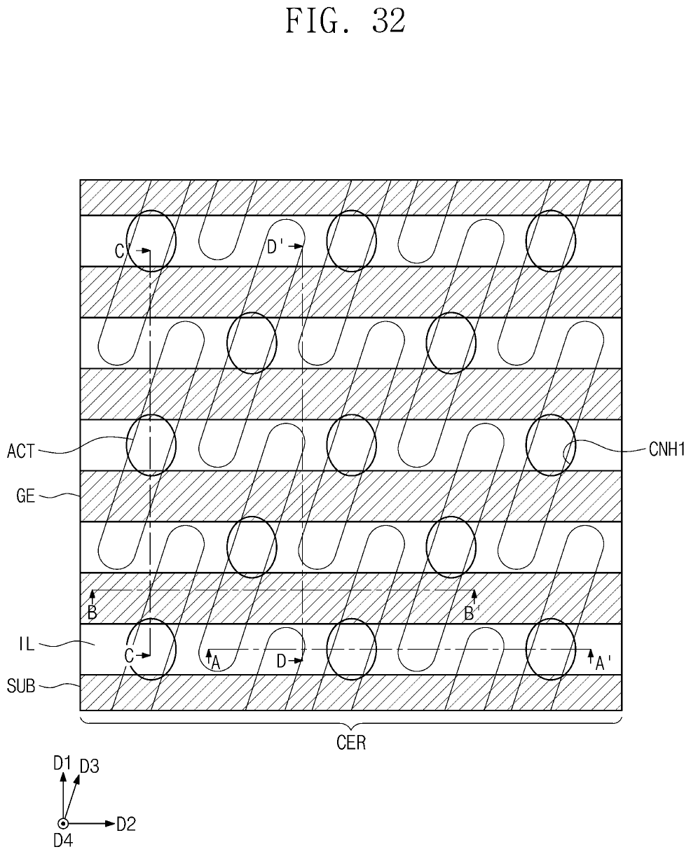

Referring to FIGS. 30 and 31A to 31D, a gate insulating layer GI, a gate electrode GE, and a gate capping layer GP may be sequentially formed in each of the third trenches

TR3. In detail, the gate insulating layer GI may be formed to conformally at least partially cover the third trench TR3. The gate insulating layer GI may include a silicon oxide layer, a silicon nitride layer, a silicon oxynitride layer, and/or a high-k dielectric layer.

The gate electrode GE may be formed on the gate insulating layer GI by forming a conductive layer to at least partially fill the third trench TR3. The conductive layer may be formed of or include one or more conductive metal nitrides and/or metallic materials.

The gate insulating layer GI and the gate electrode GE may be recessed to form an empty region and then, the gate capping layer GP may be formed in the empty region or on the recessed gate electrode GE. The gate capping layer GP may be formed to have a top surface that is coplanar with the top surface of the active pattern ACT.

An ion implantation process may be performed on the active patterns ACT to form a first source/drain region SD1 and a pair of second source/drain regions SD2 in an upper portion of the active pattern ACT. The pair of second source/drain regions SD2 may be spaced apart from each other in the third direction D3, with the first source/drain region SD1 interposed therebetween. In an embodiment, the first and second source/drain regions SD1 and SD2 may be doped with the same impurities.

A channel region CH may be defined in a portion of the active pattern ACT located below the gate electrode GE in the D4 direction. When viewed in a plan view, the channel region CH may be interposed between the first source/drain region SD1 and the second source/drain region SD2. The gate electrode GE may be provided on the top surface and opposite side surfaces of the channel region CH (e.g., see FIG. 31B).

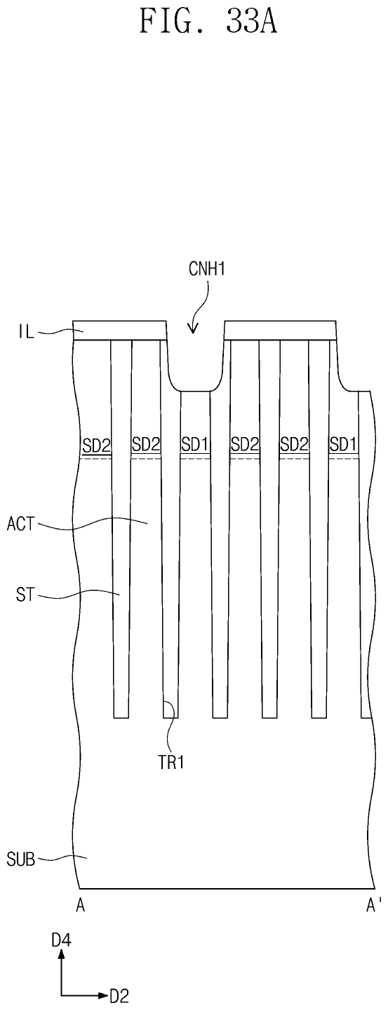

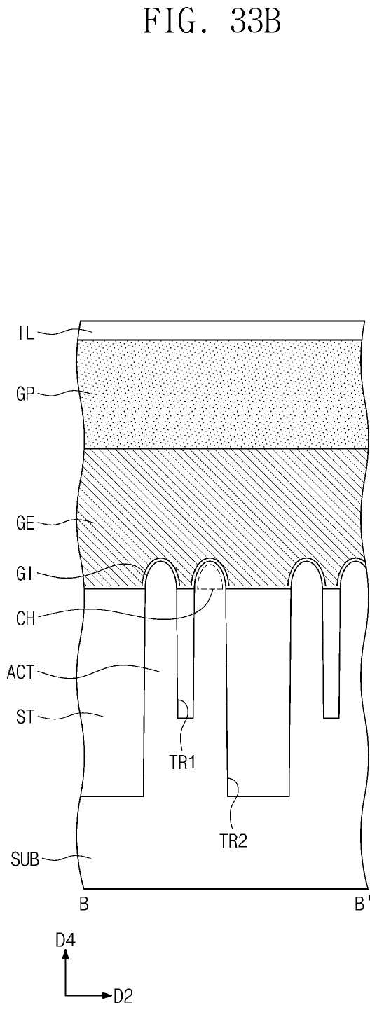

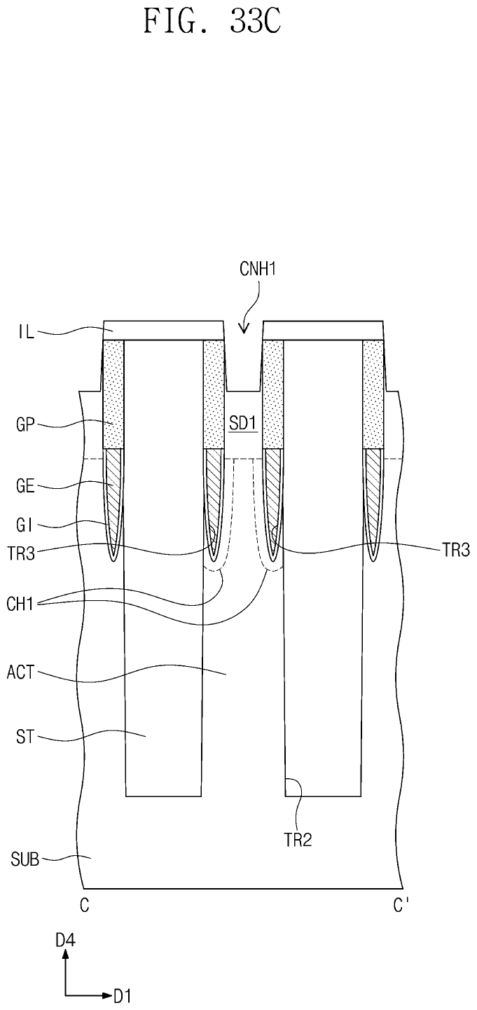

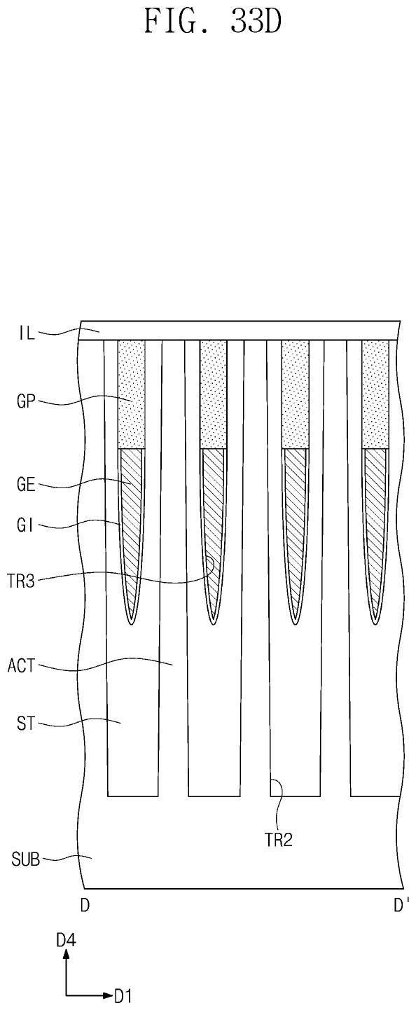

Referring to FIGS. 32 and 33A to 33D, an insulating layer IL may be formed on the substrate SUB. As an example, the insulating layer IL may be a multi-layered structure, in which a silicon oxide layer and a silicon oxynitride layer are stacked. The insulating layer IL may be patterned to form first contact holes CNH1, each of which exposes a corresponding one of the first source/drain regions SD1 of the active patterns ACT. When the first contact hole CNH1 is formed, an upper portion of the first source/drain region SD1 may be partially recessed. Similarly, when the first contact hole CNH1 is formed, an upper portion of the device isolation layer ST around the first source/drain region SD1 may be partially recessed.

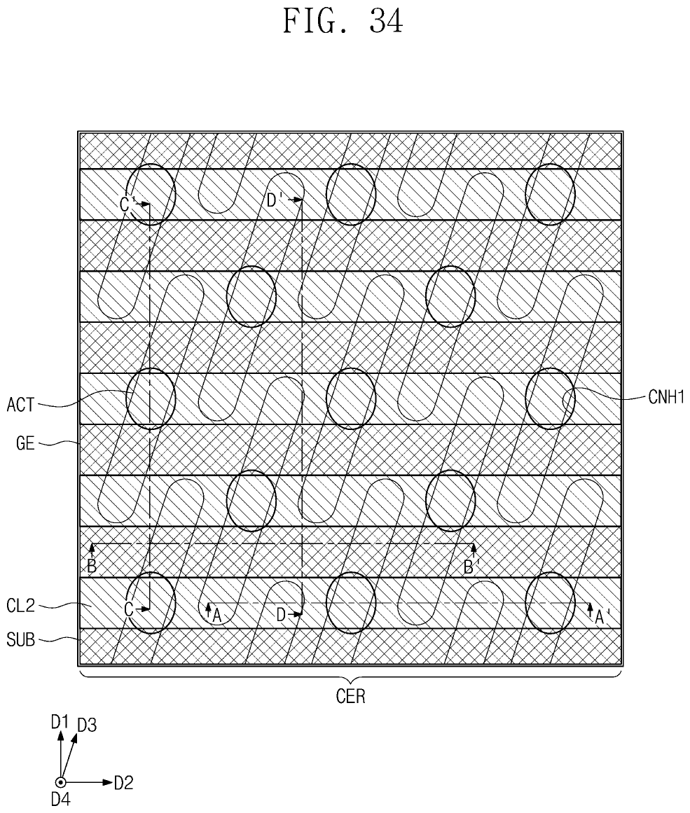

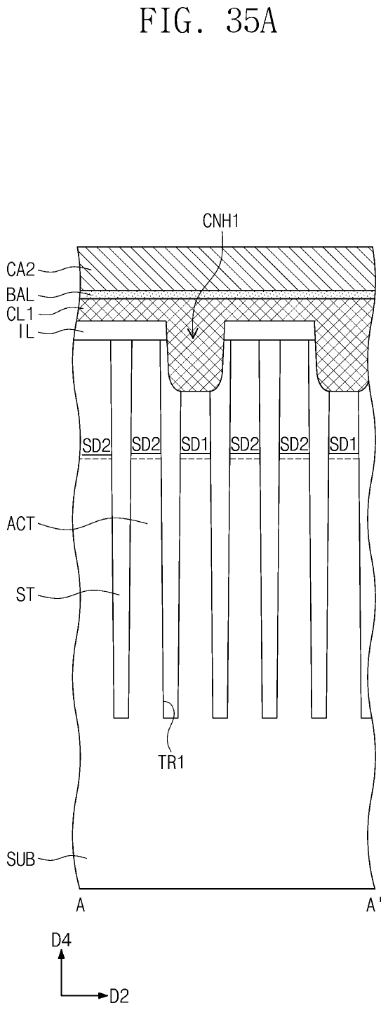

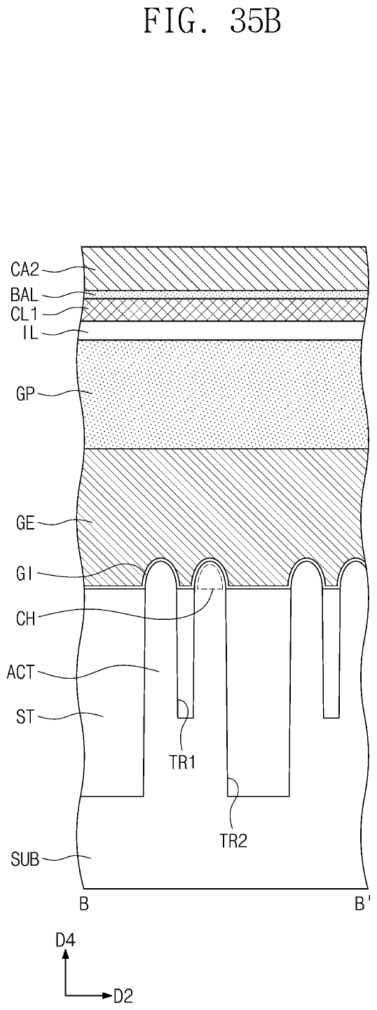

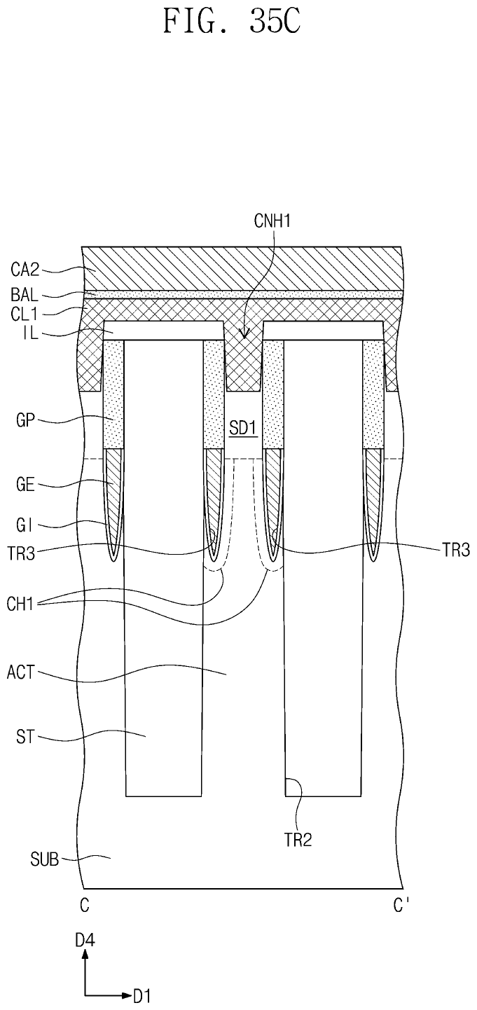

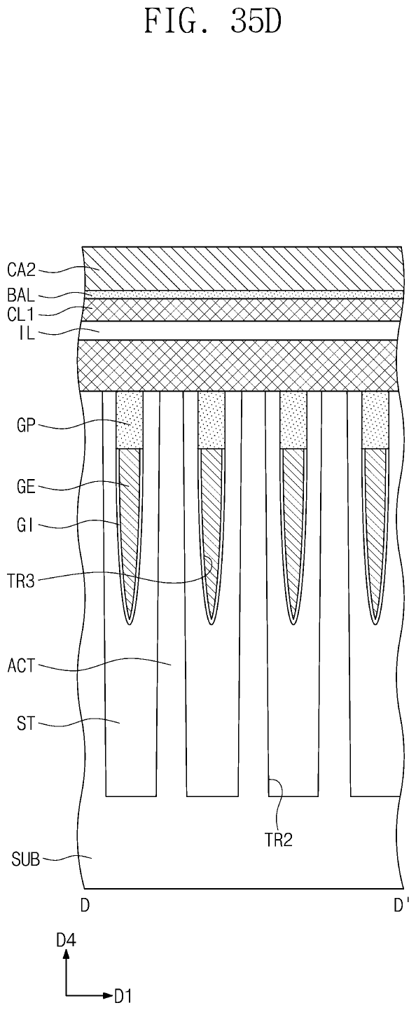

Referring to FIGS. 34 and 35A to 35D, a first conductive layer CL1, a barrier layer BAL, and a second conductive layer CL2 may be sequentially formed on the insulating layer IL. The first conductive layer CL1 may at least partially fill the first contact holes CNH1. In other words, the first conductive layer CL1 may be in contact with the first source/drain regions SD1 of the active patterns ACT. The first conductive layer CL1 may be vertically, i.e., D4 direction, spaced apart from the second source/drain regions SD2 of the active patterns ACT by the insulating layer IL. The first conductive layer CL1 may be formed of or include one or more doped semiconductor materials.

The barrier layer BAL may be formed to be interposed between the first conductive layer CL1 and the second conductive layer CL2. The barrier layer BAL may be formed of or include one or more conductive metal nitrides. The second conductive layer CL2 may be formed of or include one or more metallic materials. The barrier layer BAL may prevent or suppress a metallic material in the second conductive layer CL2 from being diffused into the first conductive layer CL1.

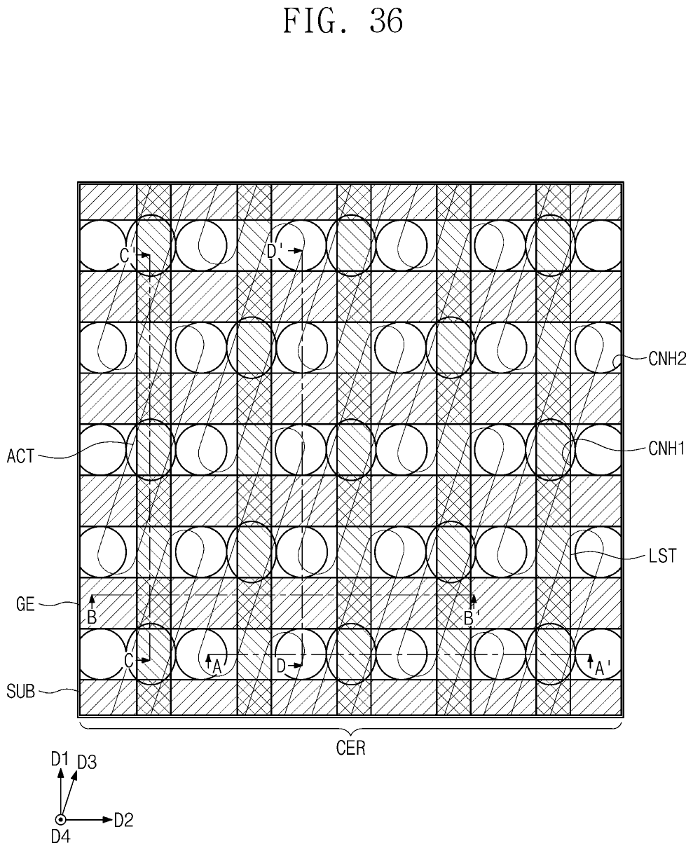

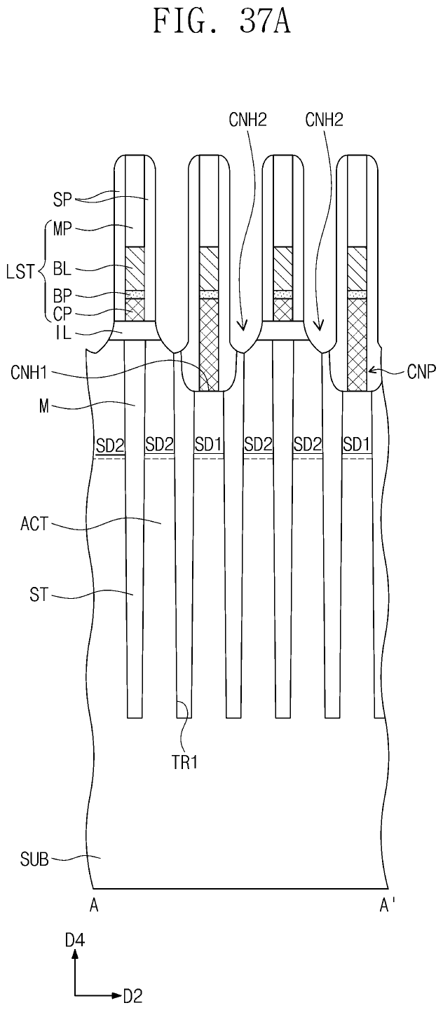

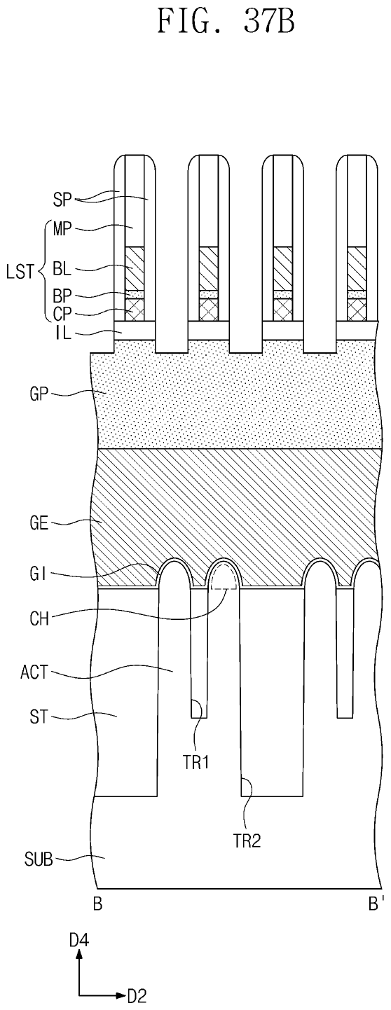

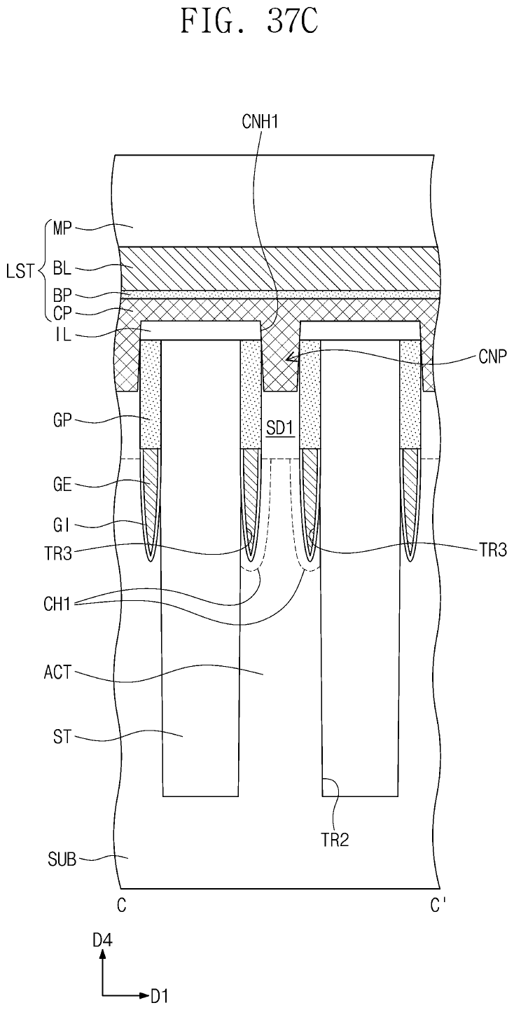

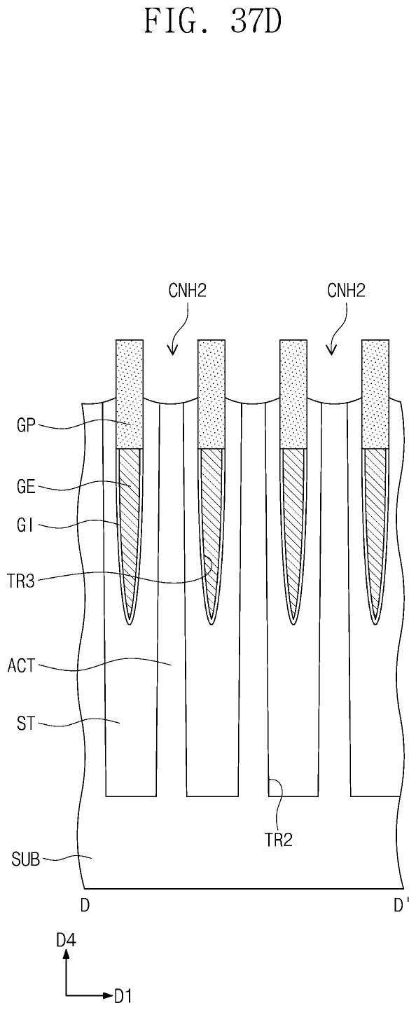

Referring to FIGS. 36 and 37A to 37D, line structures LST may be formed on the insulating layer IL to be extended in the first direction DI and parallel to each other. The line structures LST may be arranged in the second direction D2.

In detail, mask patterns MP may be formed on the second conductive layer CL2. The mask patterns MP may be formed in a line shape extending in the first direction D1. As an example, the mask patterns MP may be formed of or include silicon nitride and/or silicon oxynitride.

A bit line BL, a barrier pattern BP, and a conductive pattern CP may be formed by sequentially patterning the second conductive layer CL2, the barrier layer BAL, and the first conductive layer CL1 using the mask patterns MP as a mask. The mask pattern MP, the bit line BL, the barrier pattern BP, and the conductive pattern CP may be vertically, i.e., D4 direction, overlapped with each other. The mask pattern MP, the bit line BL, the barrier pattern BP, and the conductive pattern CP may constitute the line structure LST. When viewed in a plan view, the bit lines BL may be extended to cross the gate electrodes GE.

The conductive pattern CP may include contact portions CNP at least partially filling the first contact holes CNH1, respectively. The conductive pattern CP may be connected to the first source/drain region SD1 through the contact portion CNP. In other words, the bit line BL may be electrically connected to the first source/drain region SD1 through the conductive pattern CP.

A pair of spacers SP may be formed on opposite side surfaces of each of the line structures LST. The formation of the spacers SP may include conformally forming a spacer layer on the entire top surface of the substrate SUB and anisotropically etching the spacer layer.

An etching process using the spacers SP and the mask patterns MP as a mask may be performed on the entire top surface of the substrate 100 to form second contact holes CNH2 exposing the second source/drain regions SD2, respectively. In detail, the second contact hole CNH2 may be formed to penetrate the insulating layer IL and may be extended to a level lower in the D4 direction than the top surface of the substrate SUB. When the second contact hole CNH2 is formed, an upper portion of the second source/drain region SD2 may be partially recessed. When the second contact hole CNH2 is formed, an upper portion of the device isolation layer ST around the second source/drain region SD2 may be partially recessed.

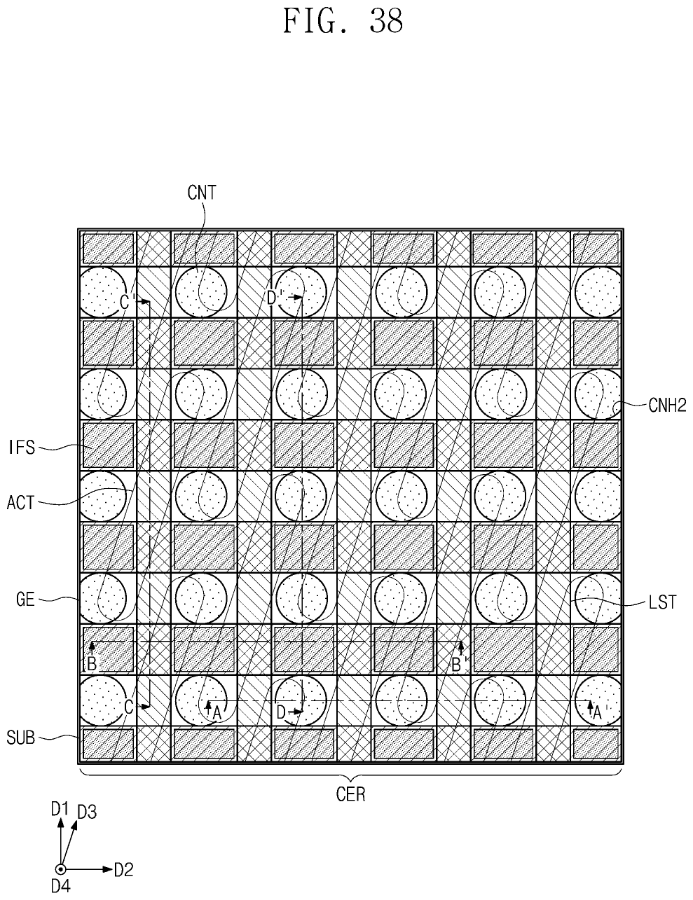

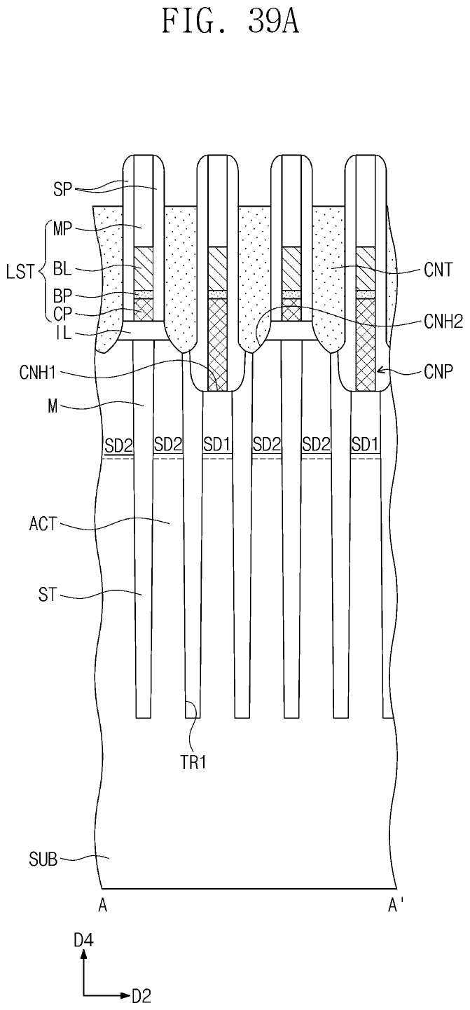

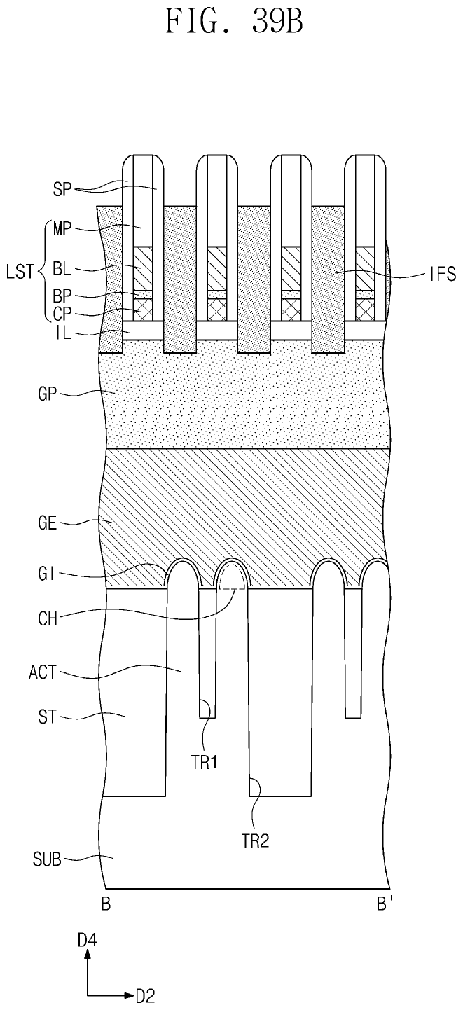

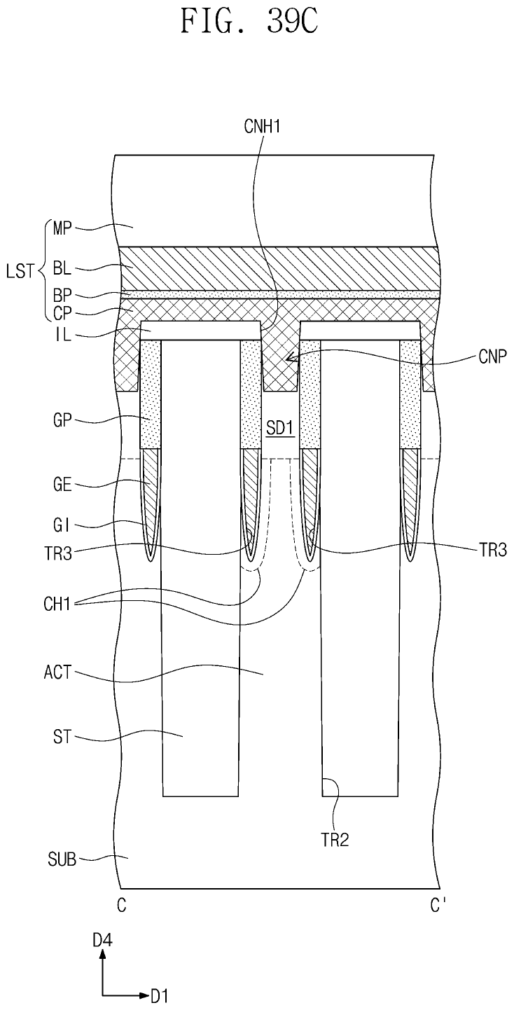

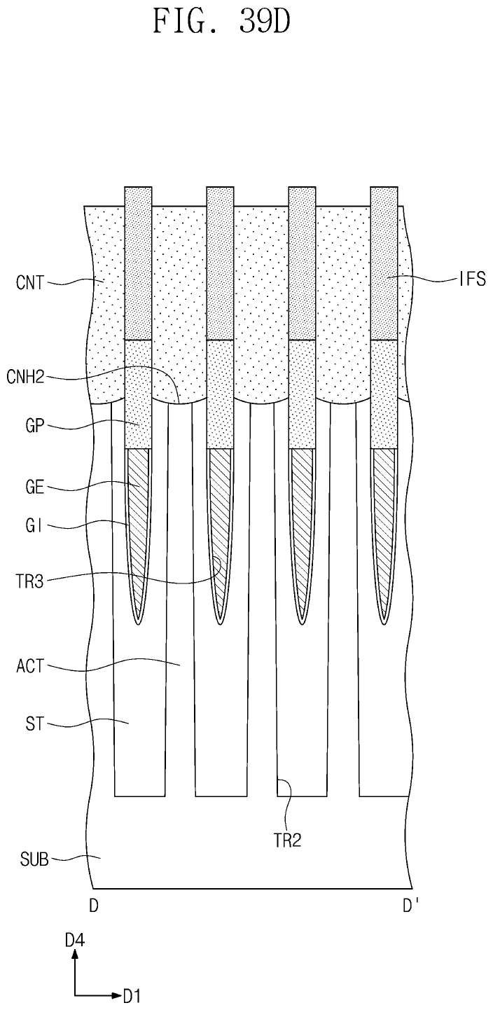

Referring to FIGS. 38 and 39A to 39D, a plurality of insulating fences IFS may be formed on the gate capping layer GP. The insulating fences IFS may not overlap the second contact holes CNH2 and may expose the second contact holes CNH2.

Contacts CNT may be respectively formed in the second contact holes CNH2 by at least partially filling the second contact holes CNH2 with a conductive material. The contacts CNT may be connected to the second source/drain regions SD2. In detail, the conductive material may be formed on the entire top surface of the substrate SUB and then may be recessed until a top surface of the conductive material is lower in the D4 direction than top surfaces of the insulating fences IFS. In this case, the conductive material may be cut by the insulating fences IFS, and as a result, the contacts CNT may be formed in the second contact holes CNH2, respectively. The contacts CNT and the insulating fences IFS may be alternately arranged in the first direction D1.

The conductive material at least partially filling the second contact holes CNH2 may be formed of or include one or more doped semiconductor materials. In an embodiment, the second contact holes CNH2 may be at least partially filled with a doped semiconductor material, and then, impurities in the semiconductor material may be diffused into the second source/drain regions SD2.

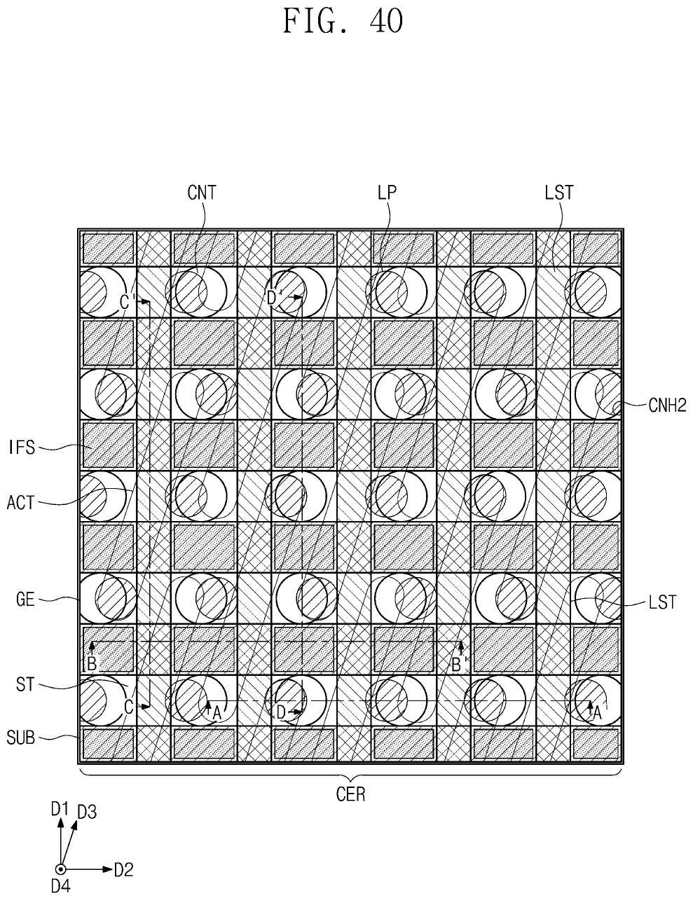

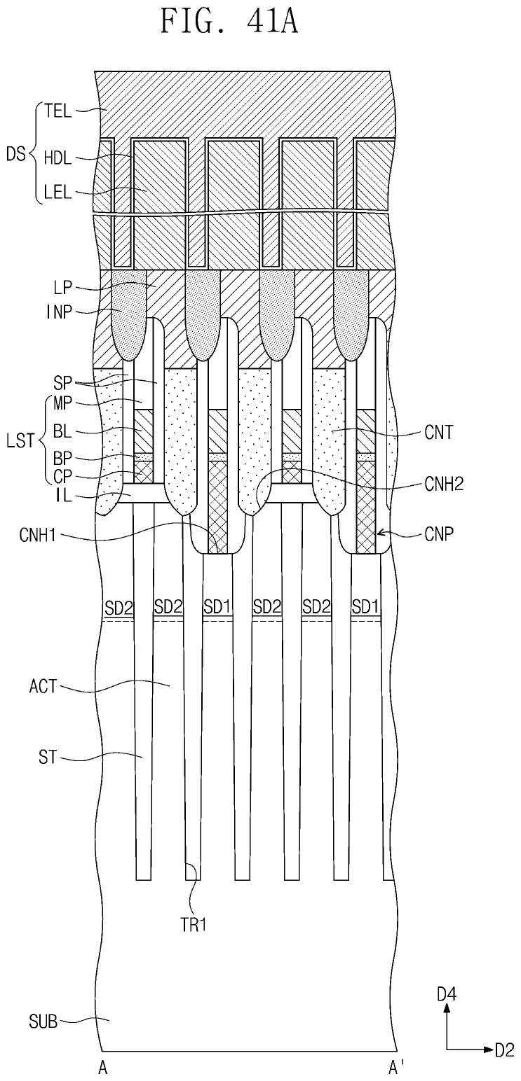

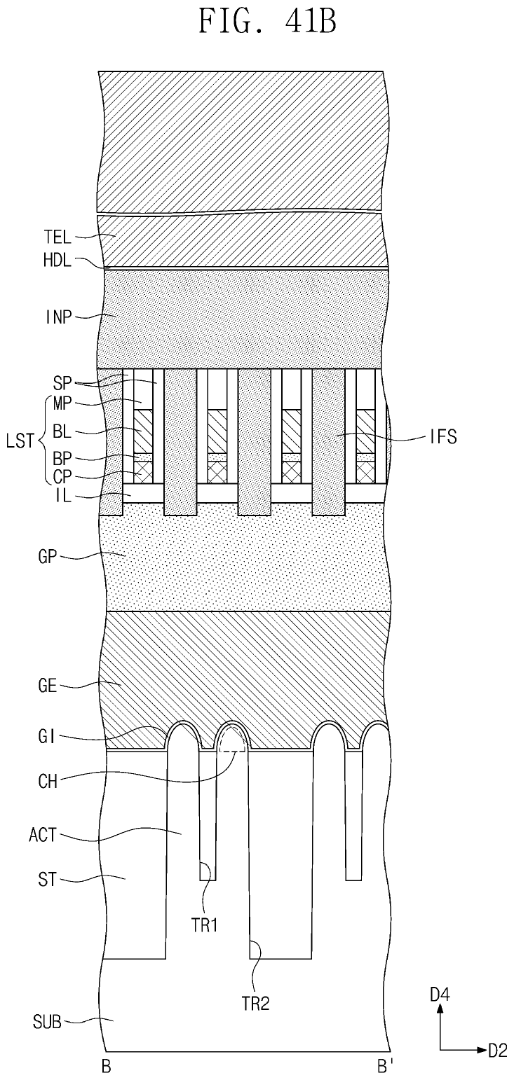

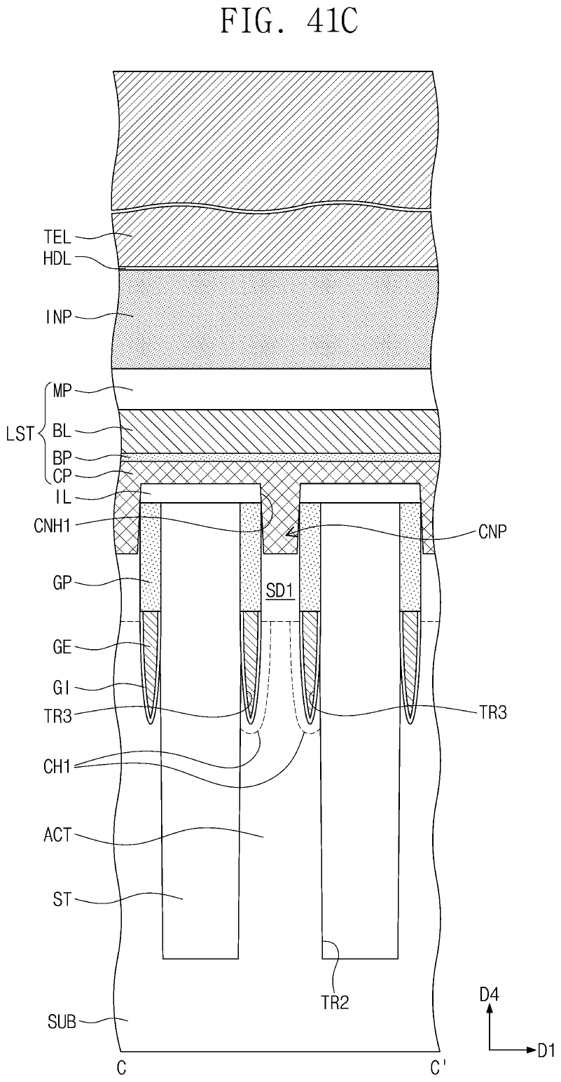

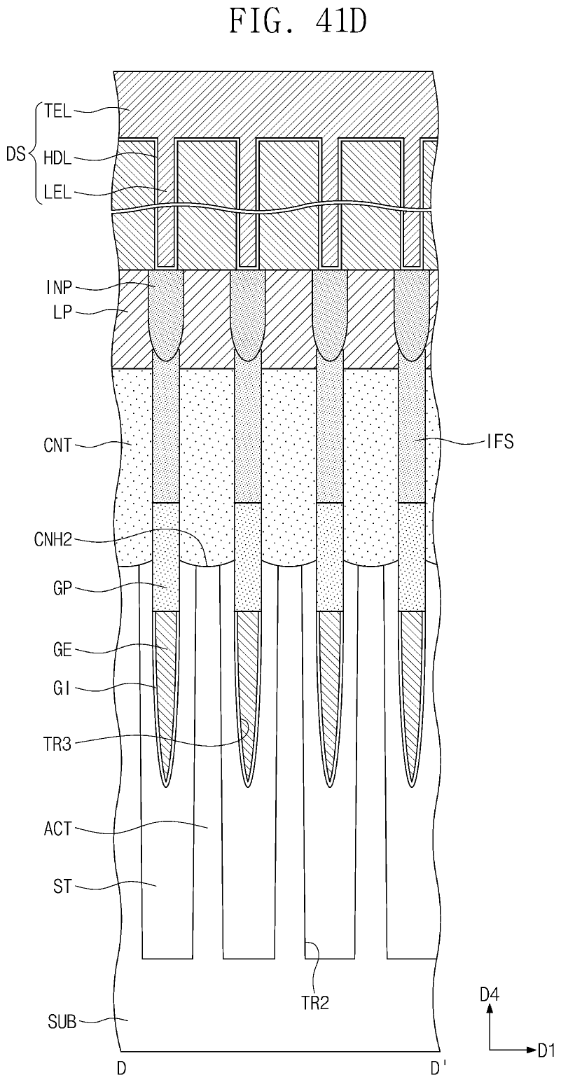

Referring to FIGS. 40 and 41A to 41D, landing pads LP may be formed on the contacts CNT, respectively. In detail, a metal layer may be formed on the contacts CNT and the insulating fences IFS. The landing pads LP may be formed by patterning the metal layer.

The patterning of the metal layer may be performed using the photolithography process previously described with reference to FIGS. 24 and 25. The photomask 1400 previously described with reference to FIG. 24 may be used as a photomask for forming the landing pads LP. In other words, the photomask for forming the landing pads LP may be manufactured through the OPC method described with reference to FIGS. 9 to 23.

Since the photomask manufactured through the afore-described OPC method is used to form the landing pads LP, the landing pads LP may be precisely formed, even when the landing pads LP have fine sizes and fine pitches. Thus, it may be possible to form the landing pads LP on the contacts CNT, respectively, without a process defect issue.

An insulating pattern INP may be formed by at least partially filling a space between the landing pads LP with an insulating material. First electrodes LEL may be formed on the landing pads LP, respectively. The afore-described photolithography process may be used as a part of a patterning process to form the first electrodes LEL.

A dielectric layer HDL may be conformally formed on the first electrodes LEL. A second electrode TEL may be formed on the dielectric layer HDL. The first electrode LEL, the dielectric layer HDL, and the second electrode TEL may constitute a data storing element DS (e.g., a capacitor). Although not shown, metal layers (e.g., M1, M2, M3, M4, and so forth) may be further formed on the second electrode TEL.

In an OPC method according to an embodiment of the inventive concept, a representative cell, on which an OPC process will be executed, may be chosen using information on cell hierarchy, and the OPC process may be selectively executed on a unique segment, which is selected in the representative cell. In this case, it may be possible to maintain the consistency of the OPC process and reduce the execution time of the OPC process.

While example embodiments of the inventive concept have been particularly shown and described, it will be understood by one of ordinary skill in the art that variations in form and detail may be made therein without departing from the spirit and scope of the attached claims.

What is claimed is:

1. A method of fabricating a semiconductor device, comprising:
performing optical proximity correction (OPC) on a design pattern of a layout; and
forming a photoresist pattern on a substrate using a photomask manufacture based the corrected layout,
wherein the performing of the OPC comprises:
analyzing a cell hierarchy to choose a representative cell in the layout;
dividing the design pattern in the representative cell into a plurality of segments including first segments;
choosing a first unique segment, which represents the first segments, from the plurality of segments;
generating a first correction bias of the first unique segment;
applying the first correction bias to all of the first segments to generate a correction pattern; and
applying a correction result of the representative cell to other cells that are included in the layout and are of a same type as the representative cell.

2. The method of claim 1, wherein the choosing of the first unique segment comprises:
generating a hash value for each of the segments;
searching the first segments, all of which have a first hash value, from the plurality of segments; and
choosing one of the first segments as the first unique segment.

3. The method of claim 2, wherein the generating of the hash value comprises:
generating a query region centered on a target segment of the plurality of segments; and
generating the hash value based on a pattern image in the query region.

4. The method of claim 3, wherein the hash value is generated based on first information pertaining to the target segment and second information pertaining to other segments of the plurality of segments around the target segment.

5. The method of claim 1, wherein the plurality of segments further include second segments,
wherein the performing of the OPC further comprises:
choosing a second unique segment, which represents the second segments, from the plurality of segments;
generating a second correction bias of the second unique segment; and
applying the second correction bias to all of the second segments, and
wherein the second correction bias is different from the first correction bias.

6. The method of claim 5, wherein all of the first segments have a first hash value,
wherein all of the second segments have a second hash value, and
wherein the first hash value is different from the second hash value.

7. The method of claim 1, wherein the representative cell comprises a first patch, a second patch, and a patch boundary therebetween.

8. The method of claim 1, wherein the layout is a layout of a memory device.

9. The method of claim 1, wherein the performing of the OPC further comprises performing a mask rule check on the correction pattern.

10. The method of claim 1, further comprising:
forming a device isolation layer on the substrate to define an active pattern;
forming a gate electrode to cross the active pattern;
forming a first source/drain region and a second source/drain region, which are respectively adjacent to opposite sides of the gate electrode, in an upper portion of the active pattern;
forming a bit line, which is electrically coupled to the first source/drain region;
forming a contact, which is electrically coupled to the second source/drain region;
forming a metal layer on the contact;
patterning the metal layer using the photoresist pattern to form a landing pad; and
forming a data storing element on the landing pad.

11. A method of fabricating a semiconductor device, comprising:
performing optical proximity correction (OPC) on a layout of a memory device; and
forming a photoresist pattern on a substrate using a photomask manufacture based on the corrected layout,
wherein the performing of the OPC comprises:
choosing a representative cell from a plurality of cells in the layout;
dividing a design pattern in the representative cell into a plurality of segments;
choosing a unique segment from the plurality of segments; and
generating a correction bias of the unique segment.

12. The method of claim 11, wherein the choosing of the unique segment comprises:
generating a hash value for each of the plurality of segments;
searching first segments, all of which have a first hash value, from the plurality of segments; and
choosing one of the first segments as the unique segment.

13. The method of claim 12, wherein the generating of the hash value comprises:
generating a query region centered on a target segment; and
generating the hash value based on a pattern image in the query region.

14. The method of claim 11, further comprising:
applying the correction bias to the unique segment; and
applying the correction bias to other segments of the plurality of segments, which have a same hash value as the unique segment, in a same manner.

15. The method of claim 11, further comprising applying a correction result of the representative cell to other cells of the plurality of cells in the layout.

16. A method of fabricating a semiconductor device, comprising:
performing an optical proximity correction (OPC) on a design pattern of a layout;
manufacturing a photomask based on the corrected layout;
forming an etch-target layer and a photoresist layer on a substrate;
performing a photolithography process using the photomask on the photoresist layer to form photoresist patterns; and
patterning the etch-target layer using the photoresist patterns,
wherein the performing of the OPC comprises:
analyzing a cell hierarchy to choose a representative cell in the layout;
dividing the design pattern in the representative cell into a plurality of segments including first and second segments;
choosing a first unique segment, which represents the first segments, from the plurality of segments;
choosing a second unique segment, which represents the second segments, from the plurality of segments;
generating a first correction bias of the first unique segment;
generating a second correction bias of the second unique segment;
applying the first correction bias to all of the first segments; and
applying the second correction bias to all of the second segments.

17. The method of claim 16, wherein the choosing of the first and second unique segments comprises:
generating a hash value for each of the plurality of segments;
searching the first segments, all of which have a first hash value, from the plurality of segments;
searching the second segments, all of which have a second hash value, from the plurality of segments;
choosing one of the first segments as the first unique segment; and
choosing one of the second segments as the second unique segment,
wherein the first hash value is different from the second hash value.

18. The method of claim 16, wherein the first correction bias and the second correction bias are different from each other.

19. The method of claim 16, wherein the performing of the OPC further comprises applying a correction result of the representative cell to other cells that are included in the layout and are of a same type as the representative cell.

20. The method of claim 16, wherein the layout is a layout of a memory device.
